(19) United States
(12) Patent Application Publication
(10) Pub. No.: US 2009/0090617 A1
(43) Pub. Date: Apr. 9, 2009

(54) Method and Apparatus for Producing Controlled Stresses and Stress Gradients in Sputtered Films

(76) Inventors: Pierre H. Giauque, San Francisco, CA (US); Fu Chiung Chong, Saratoga, CA (US); Frank Swiatowiec, San Jose, CA (US); Donald Smith, Bolinas, CA (US)

Correspondence Address: GLENN PATENT GROUP, 3475 EDISON WAY, SUITE L, MENLO PARK, CA, 94025, US

(21) Appl. No.: 11/995,490

(22) PCT Filed: Jul. 14, 2006
(86) PCT No.: PCT/US06/27423

§ 371 Date: Dec. 5, 2008

Related U.S. Application Data
(60) Provisional application No. 60/699,647, filed on Jul. 14, 2005.

(51) Int. Cl. C23C 14/34; C23C 14/54

(52) U.S. Cl. 204/192.15; 204/298.11; 204/192.12; 427/9

(57) ABSTRACT

An enhanced sputtered film processing system and associated method comprises one or more sputter deposition sources each having a sputtering target surface and one or more side shields extending therefrom, to increase the relative collimation of the sputter deposited material, such as about the periphery of the sputtering target surface, toward workpiece substrates. One or more substrates are provided, wherein the substrates have a front surface and an opposing back surface, and may have one or more previously applied layers, such as an adhesion or release layer. The substrates and the deposition targets are controllably moved with respect to each other. The relatively collimated portion of the material sputtered from the sputtering target surface travels beyond the side shields and is deposited on the front surface of the substrates. The increase in relative collimation results in deposited films with desirable properties including but not limited to high levels of both readily controllable compressive stress and mechanical integrity without the use of ion bombardment.

### FIELD OF THE INVENTION

The invention relates to the deposition of films having controlled levels of stress and stress gradients on support substrates. More particularly, the invention relates to methods and apparatus for fabrication of films having controlled levels of uniform and or isotropic stresses and stress gradients on substrates and the application of such films to the fabrication of photolithographically patterned spring contacts.

### BACKGROUND OF THE INVENTION

Thin films are often deposited on substrates by sputtering in glow-discharge plasmas, where ions accelerated out of the plasma knock atoms off of the target (source) material, which are then transported to the substrate. A magnetically confined plasma generator i.e. magnetron, is typically used to increase sputtering efficiency and to reduce the minimum operating pressure. Sputtering is a preferred deposition technique because it can be used for any material, because the energy of the depositing atoms helps film adherence, and because the substrate temperature remains relatively low throughout the deposition process.

Uniformity of film thickness across large substrate areas is usually important in microfabricated devices. One of two approaches is conventionally taken to achieve film thickness uniformity.

One such approach is to position the substrates at a radius far from the target relative to substrate and target diameters. To increase throughput and use targets efficiently, many substrates are positioned at this radius over most of a hemisphere and are kept in a planetary (two-axis) motion so that they occupy a wide range of positions over the hemisphere during the course of the deposition time. This averages out deposition rate variation over the hemisphere.

A second approach uses a rectangular target that is larger than the substrate in the target's long dimension. The substrate is placed close to the target and is passed back and forth across it in linear transport so that the substrate is painted with a uniform swath of film in successive layers much like painting with a roller. Typically 100 nm of film are deposited in each pass. Planetary motion systems have also been used to increase the thickness uniformity of material deposited from rectangular sources by randomizing the path of the substrates relative to the deposition sources, e.g. setting the rotation rate of the substrate about its axis to be much greater than the rotation rate of primary axis of the planetary motion system.

Sputtering is used in the fabrication of various microelectronic structures. For example, D. Smith and S. Alimonda, Photolithographically Patterned Spring Contact, U.S. Pat. No. 5,613,861 (25 Mar. 1997), U.S. Pat. No. 5,848,685 (15 Dec. 1998), and International Patent Application No. PCT/US 96/08018 (Filed 30 May 1996), describe a photolithographically patterned spring contact, which is “formed on a substrate and electrically connects contact pads on two devices.”

Photolithographically patterned spring structures are particularly useful in electrical contactor applications where it is desired to provide high density electrical contacts which may extend over relatively large contact areas and which also may exhibit relatively high mechanical compliance in the normal direction relative to the contact area. Such electrical contactors are useful for applications including integrated circuit device testing (both in wafer and packaged formats), integrated circuit packaging (including singulated device packages, wafer scale packaging, and multiple chip packages) and electrical connectors (including board level, module level, and device level, e.g. sockets.

In addition to providing compliance in the direction normal to the contact plane, photolithographically patterned spring contacts also compensate for thermal and mechanical variations and other environmental factors. An internal stress gradient within the spring contact causes a free portion of the spring to bend up and away from the substrate to a lift height which is determined by the magnitude of the stress gradient. An anchor portion remains fixed to the substrate and is electrically connected to a first contact pad on the substrate. The spring contact is made of an elastic material and the free portion compliantly contacts a second contact pad, thereby contacting the two contact pads. Variations in the internal stress gradient across the substrate surface can cause variations in spring contact lift height.

The ability to produce uniform stress gradients over large substrate areas depends on being able to controllably create a sequence of thin layers of deposited metal, each having controlled levels of mechanical stress. Deposited films having internal stress gradients are characterized by a first layer having a first stress level, a series of intermediate layers having varying stress levels, and a last layer having a last stress. The magnitude of the internal stress gradient is determined by the difference in stress levels between each layer in the film. The curvature of a lifted spring is a function of the magnitude of the internal stress gradient, geometrical factors, e.g. thickness, shape, and material properties, e.g. Young's modulus. After release from the substrate, the free portion of the spring deflects upward until the stored energy is minimized.

For a given curvature, thicker springs require a greater range of stresses than do thinner springs. Thicker springs are preferred when higher forces at a given deflection are required. For example, in certain electrical contactor applications, it is desirable to fabricate spring contacts having a relatively high contact force and a high lift height to provide low electrical resistance and a high mechanical compliance range. The combination of relatively high force and relatively high lift height requires both a relatively high stress gradient and a relatively large range of stress within the deposited film. In other words, springs having relatively large forces and high lift heights typically are relatively thick and have relatively high magnitude internal stress gradients extending over a larger range of stresses.

The stress range is increased when the spring comprises at least one layer of high compressive stress and at least one layer of high tensile stress. There is an upper limit to the compressive and tensile stresses that a thin film can sustain without loosing mechanical integrity.

In addition to controlling film thickness, it is desirable to deposit films having uniform, and controlled stress levels. In DC magnetron sputtering, low plasma pressure increases compression, higher pressure creates tensile stress, and still higher pressure results in porous films that have no mechanical strength in the film plane. There is a lower limit on the practical working pressures that can be achieved in production deposition systems and therefore there is an upper limit to the compressive stress that can be imparted to the film. However, due to its inherent simplicity, magnetron sputter-deposition of films with internal stress gradients formed by increasing plasma pressure during deposition is a presently preferred technique for implementing patterned spring technology. The stress range in a thin film can be maximized by creating compressive stress in a starting layer of a stress gradient within the film and tensile stress in an ending layer of a stress gradient within the film.

In addition to plasma pressure, the angle of incidence at which atoms are deposited on a substrate, i.e. the deposition angle, is also known by those skilled in the art to be an important determinant of film stress, with off-normal or grazing, i.e. shallow, angles of incidence resulting in more tension and, if excessive, in porosity. It is also known that atoms deposited at near normal or normal angles and/or with increased energy result in films with in increased levels of compression.

Side shields have previously been used to reduce the relative amount of deposition from magnetron deposition sources impinging on substrates at shallow angles. For example, McLeod et al., Journal of Vacuum Science Technology, Vol. 14, No. 1, January/February 1977, teach the use of side shields to reduce the amount of “low angle” deposition of Aluminum sputtered from a planar magnetron source to increase the reflectivity of a vapor deposited aluminum films. Side shields have also been used in the prior art for other purposes, such as to reduce the amount of sputter deposited materials on non-targeted surfaces, e.g. on the surfaces of the sputtering apparatus, on the back side of the substrate, on substrate fixtures, and/or on adjacent substrates and sputter targets.

Ion bombardment has previously been used to increase compressive stress in vacuum-deposited films. Increased levels of ion bombardment increase compressive stress and very high levels of ion bombardment result in films with compromised mechanical integrity. Additionally, ion sources operate at pressures up to about 1 milli Torr, while magnetron sputter deposition sources operate from pressures of about 0.5-1 milli Torr and above. Given the limited overlap between the ranges, it is difficult to operate an ion gun and a magnetron sputter source simultaneously in a single vacuum chamber.

It would be advantageous to provide a method and apparatus to create uniform compressive stress across the surface of large substrate areas without the use of ion bombardment from an ion source other than the sputtering target itself, such as to avoid limited overlap between operating pressure ranges ion sources and magnetron sputtering sources.

As well, while sputtering sources are capable of emitting high energy ions capable of creating compressive stress in the deposited film under proper conditions, it is not currently known within the prior art how to produce wide extremes of stress in sputtered films ranging from highly compressive to highly tensile while maintaining high uniformity across large substrate areas without the use of a secondary ion bombardment source, i.e. other than the sputtering target itself.

It would therefore be advantageous to provide a method and apparatus for producing uniform and or isotropic stresses in sputtered films wherein the stress level varies from highly compressive to highly tensile without the use of a secondary ion bombardment source.

Certain applications of photolithographically patterned spring contacts in connectors and IC device probing require that the lift height (in the Z direction) and the tip position (in X and Y direction) are tightly controlled.

It would therefore also be desirable to provide a method and apparatus capable of fabricating photolithographically patterned spring contacts with lift heights and tip positions having predictable and controllable positional errors.

It would also be desirable to provide a method and apparatus capable of fabricating spring contacts having lift heights and tip positions with predictable errors and methods for compensating for the errors to provide spring contacts having lift heights and tip positions with minimized errors.

### SUMMARY OF THE INVENTION

An enhanced sputtered film processing system and associated method comprises one or more sputter deposition sources each having a sputtering target surface and one or more side shields extending therefrom to increase the relative collimation of the sputtered material, such as about the periphery of the sputtering target surface, toward workpiece substrates. One or more substrates, i.e. workpieces, are provided, wherein the substrates have a front surface and an opposing back surface, and may have one or more previously applied layers, such as to promote adhesion of the sputtered film on the substrate. The substrates and the sputter deposition sources are controllably moved with respect to each other. The increase in relative collimation due to the side shields enables the formation of films with desirable properties including but not limited to high mechanical integrity and controllable internal stress up to the maximum stress that the sputter deposited material can sustain.

At least a first portion of the material sputtered from the sputtering target surface at shallow angles is blocked by the side shields, thereby increasing the relative collimation of the one or more sputter deposition sources, while at least a second portion of the material sputtered from the sputtering target at normal or near normal angles travels beyond the side shields and is deposited on the front surface of the substrates, such that the deposited films preferably comprise high mechanical integrity and/or controllable levels of film stress in the X-Y plane parallel to the substrate.

Desired levels of film stress, ranging from highly compressive to highly tensile, can be achieved by varying sputter deposition conditions such as the deposition gas pressure. If the number of desired passes is determined to be complete, the process is ended. If the process is not done, the relative planar position and angular rotation of any of the substrates and the deposition sources may be controllably changed, and the process is repeated for further controlled deposition.

The enhanced sputtered film processing system and associated method can be used to fabricate a resulting film with substantially uniform thickness and isotropic stress by laminating two or more thin film layers deposited on a substrate. The method comprises moving the sputter deposition sources and the substrates with respect to each other in a predetermined manner during the deposition of each of the two or more thin film layers such that any X-Y anisotropy in stress in each of the two or more thin film layers (in the plane parallel to the substrate), arising from X-Y anisotropy in the deposition angle from the at least one deposition source, is averaged out.

The laminated films having substantially uniform thickness and isotropic stress fabricated using the enhanced sputtered film processing method can be combined to create a stress gradient in a composite film deposited on a substrate. The method comprises fabricating two or more laminated films each having a substantially uniform thickness and predetermined value of isotropic stress, e.g. compressive, neutral, or tensile, in the plane parallel to the substrate such that the resulting composite film comprises a stress gradient in the direction normal to the substrate, e.g. a stress gradient ranging from compressive to neutral to tensile.

The enhanced sputtered film processing system and associated method can be used to fabricate a layer having substantially uniform thickness and isotropic stress functioning as an interface layer to provide adhesion between a substrate and subsequent deposited layers of thin films. The method comprises fabricating a first adhesion layer using a first material, the adhesion layer having a substantially uniform thickness and isotropic stress and subsequently depositing at least one additional layer of at least a second material on the surface of the first adhesion layer.

The enhanced sputtered film processing system and associated method can be used to fabricate one or more springs, e.g. photolithographically patterned, on a substrate. An exemplary method comprises the steps of: forming at least one adhesion layer having a substantially uniform thickness and predetermined value of isotropic stress, subsequently forming a spring film comprising at least one spring material capable of maintaining stress over its fabrication process temperatures and subsequent operating temperatures, the spring film further comprising two or more laminated thin films each having a substantially uniform thickness and predetermined value of isotropic stress thereby forming a stress gradient in the spring film, the spring film stress gradient comprising stresses ranging from compressive to tensile, controllably removing at least a portion of the spring metal layers and the adhesion layer using photolithographic patterning, controllably chemically removing the adhesion layer between at least a portion of the photolithographically patterned one or more springs and the substrate thereby releasing the one or more springs from the substrate such that the resulting one or more spring comprises a fixed portion attached to the substrate and a free portion extending away from the substrate and thereby having a pre-determined lift height and tip position. The above methods are not limited to photolithographically patterned springs and can be used to fabricate springs patterned by other processes, such as but not limited to direct deposition of patterned spring film, micromachining of the spring film using a laser, and/or similar processes.

The enhanced sputtered film processing system and associated method can be used to fabricate spring contacts having properties, e.g. lift heights and tip positions, with predictable errors. An exemplary method for compensating for such errors, such as to provide spring contacts having properties with reduced errors, may comprise the steps of fabricating a first device on a first substrate comprising at least one spring contact, measuring the errors in the properties of the at least one spring contact in the first device, modifying the fabrication processes such as to reduce the errors in spring contact properties of subsequently fabricated devices. The measurable spring contact properties typically comprise any of spring contact length, width, shape, angular orientation, tip height and tip position.

### BRIEF DESCRIPTION OF THE DRAWINGS

FIG. 1 is a schematic plan view of an enhanced sputtered film processing system without side shields extending from sputter deposition sources;

FIG. 2 is a schematic side view of an enhanced sputtered film processing system without side shields extending from sputter deposition sources;

FIG. 3 is a schematic plan view of an enhanced sputtered film processing having side shields extending from sputter deposition sources;

FIG. 4 is a schematic side view of an enhanced sputtered film processing system having side shields extending from sputter deposition sources;

FIG. 5 shows a perspective view of a linear magnetron sputter deposition source with side shields;

FIG. 6 is an end view of a linear magnetron sputter deposition source with side shields;

FIG. 7 is a side view of a linear magnetron sputter deposition source with side shields;

FIG. 8 is an exemplary schematic view of a simplified deposition pattern from a linear magnetron sputter deposition source without side shields;

FIG. 9 is an exemplary schematic view of a simplified deposition pattern from a linear magnetron sputter deposition source having side shields;

FIG. 10 is schematic front view of a magnetron sputter deposition source without a side shield, having shallow angle incidence deposition from the ends of the target as a substrate passes by the sputter deposition source;

FIG. 11 is an end view of a magnetron sputter deposition source without a side shield, having shallow angle incidence deposition from the ends of the target as substrates pass by the sputter deposition source;

FIG. 12 is a front view of a magnetron sputter deposition source with one or more side shields, showing steeper angle of incidence deposition from the ends of the target as a substrate passes by the sputter deposition source;

FIG. 13 is an end view of a magnetron sputter deposition source with one or more side shields showing attenuated shallow incidence deposition and steeper off-normal incidence deposition from the length of the sputter deposition sources;

FIG. 14 is a simplified perspective view of a deposition pattern from a linear magnetron sputter deposition source without side shields;

FIG. 15 is a simplified perspective view showing an exemplary attenuated deposition pattern from a linear magnetron sputter deposition source having side shields;

FIG. 16 is a flowchart of an exemplary enhanced sputtering process;

FIG. 17 illustrates deposition of a material on an adhesion layer, using a magnetron sputter deposition source having a side shield;

FIG. 18 shows a deposited layer having internal stress (e.g., cpmpresive) on an adhesion layer;

FIG. 19 shows a second deposited layer on a workpiece that has been rotated;

FIG. 20 shows a composite deposition layer on an adhesion layer after two deposition passes;

FIG. 21 is a perspective view a base substrate to be used for the fabrication of pholithographically patterned springs;

FIG. 22 shows an adhesion layer formed on a base substrate;

FIG. 23 shows the formation of a multiplayer spring metal film on an adhesion layer;

FIG. 24 is a basic schematic view of photolithographic patterning on multiplayer spring metal film located on an adhesion layer;

FIG. 25 shows the result of photolithographic patterning and selective removal of an adhesion layer, wherein spring tips are lifted away from the substrate;

FIG. 26 is a schematic depiction of stress metal springs having different orientations with respect to a support substrate, and having uniform lift without twist;

FIG. 27 is a schematic view of pholithographically patterned multilayer springs having uniform and isotropic levels of stress and uniform and non-isotropic levels of stress;

FIG. 28 is a schematic view of pholithographically patterned multilayer springs having uniform and non-isotropic levels of stress;

FIG. 29 illustrates a method for modeling the change in deposition pattern due to the addition of side shields from an idealized single line sputter deposition source placed in the center of the actual sputter deposition source;

FIG. 30 illustrates a method for modeling the change in deposition pattern due to the addition of side shields from an idealized double line deposition sources placed in the corners of the box formed by the actual sputter deposition source and the side shields;

FIG. 31 is an experimentally obtained stress vs. pressure curve with MoCr deposited from sputter deposition sources without side shields, wherein data at 1 milliTorr was obtained with ion gun bombardment;

FIG. 32 is an experimentally obtained stress vs. pressure curve with MoCr deposited from sputter deposition sources with side shields and no ion gun bombardment;

FIG. 33 is an experimentally obtained spring lift height vs. titanium deposition pressure curve;

FIG. 34 is an experimentally obtained titanium stress vs. titanium deposition pressure curve;

FIG. 35 is experimental data showing lift height distribution across a 6″ substrate using a single titanium sputter deposition source equipped without side shields;

FIG. 36 is experimental data showing lift height distribution across a 6″ substrate using dual titanium sputter deposition sources equipped with and without side shields;

FIG. 37 is experimental data comparing lift height distributions across a 4″ substrate using single and dual titanium sputter deposition sources equipped with side shields.

### DETAILED DESCRIPTION OF PREFERRED EMBODIMENTS

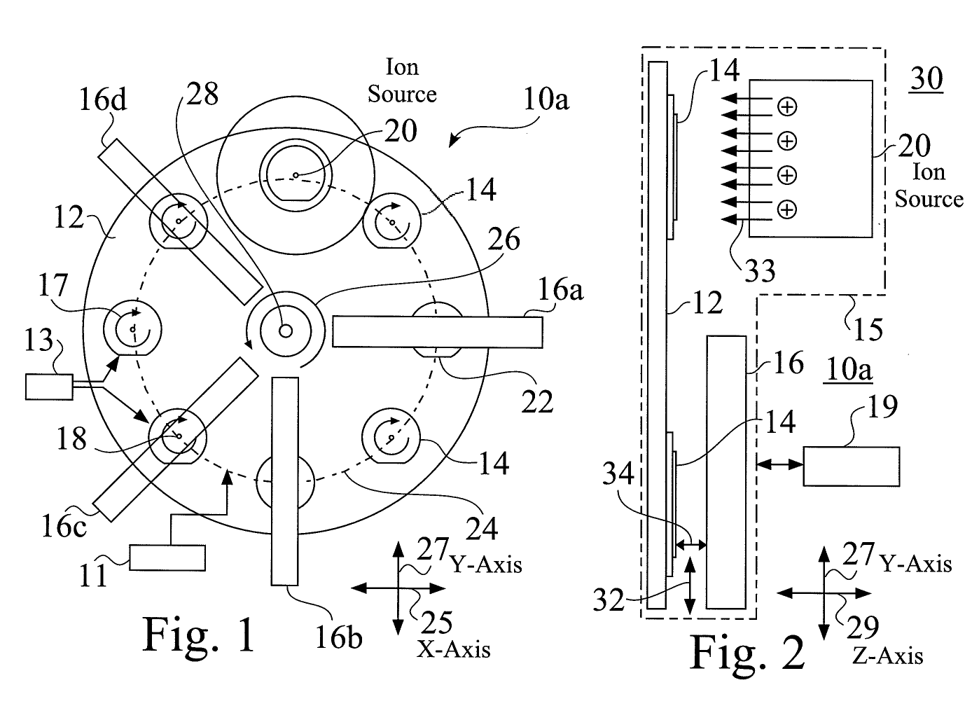

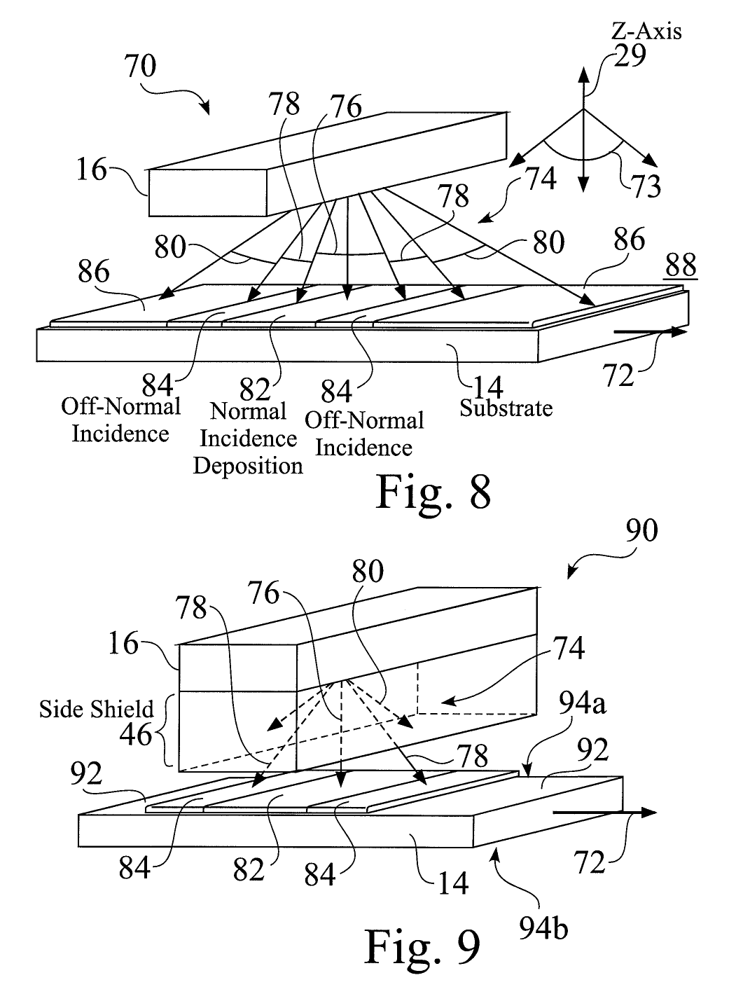

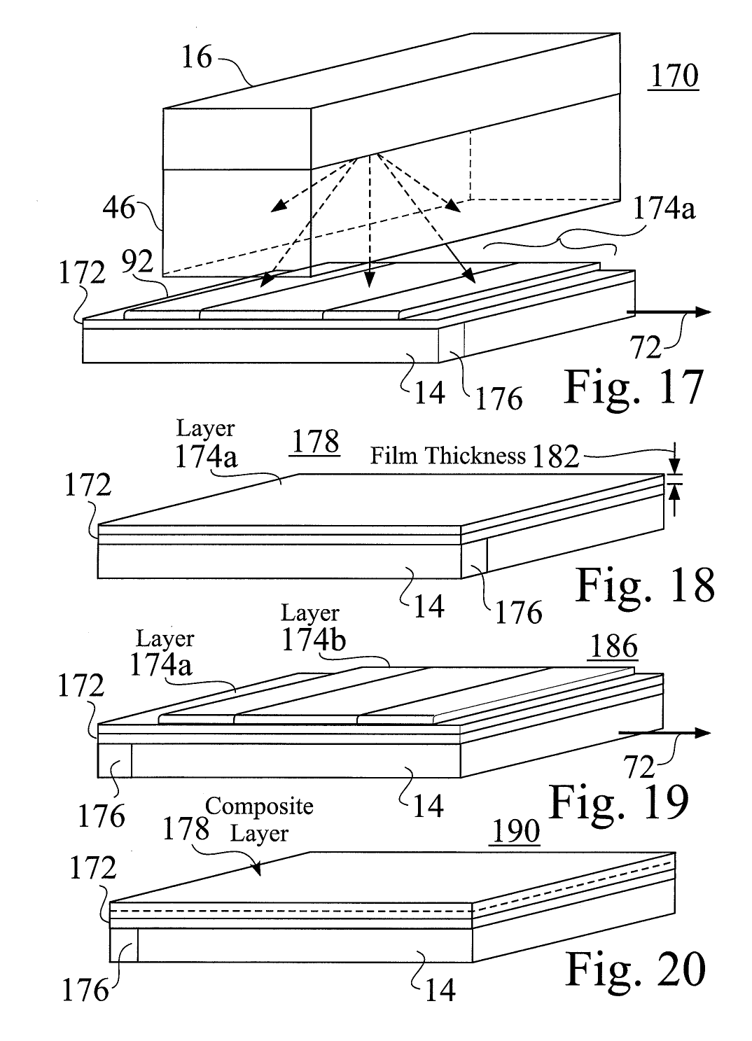

FIG. 1 is a schematic plan view of planetary enhanced sputtering film processing system 10a and placement of sputter deposition sources 16, e.g. 16a-16d, and an ion gun 20 for enhanced sputtered film processing, such as for producing controlled stresses and/or stress gradients in one or more layers 174 (FIGS. 18-20) of sputtered materials 74 (FIG. 8).

FIG. 2 is a schematic side view 30 of a planetary system 10a and placement of sputter deposition sources 16 and an ion gun 20 for enhanced sputtered film processing, such as for producing controlled stresses and/or stress gradients in one or more layers 164 of sputtered materials 74.

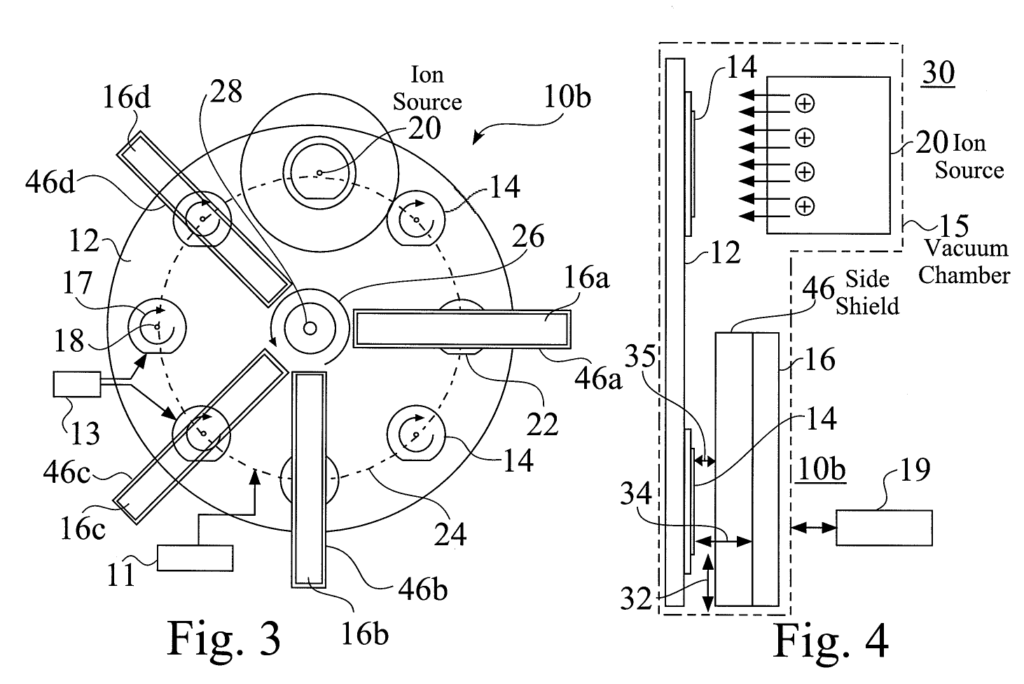

FIG. 3 and FIG. 4 respectively provide a schematic plan and side views of an enhanced sputtered film processing system 10b having side shields 46, e.g. 46a-46d, extending from sputter deposition sources 16, e.g. 16a-16d.

The exemplary enhanced sputtering film processing systems 10a and 10b seen in FIGS. 1-4 comprise an exemplary planetary drive mechanism, in which a carrier plate 12, e.g. such as circular or substantially circular, imparts planetary motion to the substrates 14, such that the orientation of the substrates 14 relative to each of the at least two deposition sources 16 remains constant as the substrates 16 travel about their orbit and are located centrally when passing the deposition source pairs 16a and 16b or 16c and 16d. As well, the carrier plate 12 rotates 26 about its normal axis 28 along with the affixed substrates 14, which additionally undergo a concomitant, i.e. concurrent, rotation 17 about their own normal axis 18, as measured relative to the carrier plate 12, with equal and opposite angular velocity as that of rotating carrier plate 12, so that orientation of the substrates 14 relative to the deposition sources 16 remain constant as carrier plate 12 rotates. Therefore, in typical embodiments of the enhanced sputtering film processing systems 10a and 10b, the substrates 14 and the carrier plate 12 synchronously rotate about their respective normal axes 18,28.

In the figures that follow, exemplary substrate motion is shown directly under a sputter deposition source 16 in order to describe the functioning of the side shields 46 and the effect on thin film deposition. Substrate motion can alternately be provided by any means, such as by moving the one or more substrates 14, the deposition source, the area of deposition from the sputter deposition source 16, or combinations thereof, or both. For a given sputtering deposition source 16, side shield 46, substrate to side shield distance, equivalent transport systems suitable for use with the enhanced sputtered film processing system 10 and associated method 150 may comprise any of linear, track, planetary and combinations thereof or other systems equivalent thereto.

The exemplary systems 10, such as 10a as seen in FIG. 2 and system 10b as seen in FIG. 4, illustrate the proximity of exemplary substrates 14 to a configuration comprising an ion gun 20 and a plurality of sputter deposition sources 16, e.g. such as but not limited to four sputter deposition sources 16a, 16b, 16c and 16d.

As seen in FIG. 1 and FIG. 2, for purposes of the discussion herein, the azimuthal angle is that rotating in the film plane defined by the X-axis 25 and the Y-axis 27, from +X to +Y to −X to −Y; and film stress is always biaxial, i.e. existing along both X and Y. Film stress may be anisotropic, i.e. different in X vs. Y at a given point, and it may be non-uniform in either X or Y across the substrate 14, or through the thickness of the film.

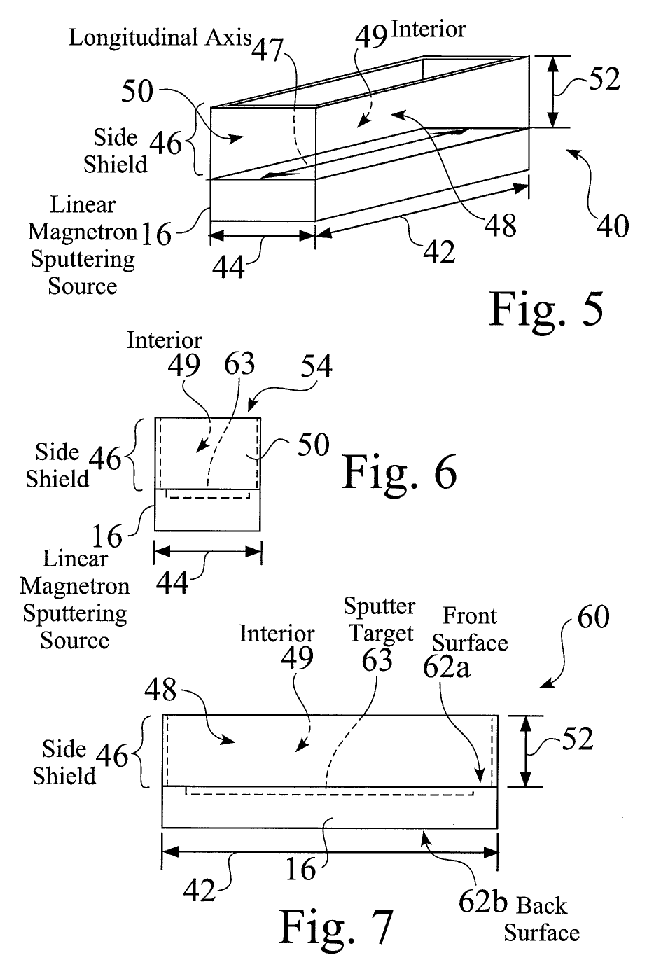

FIG. 5 shows a perspective view 40 of a linear magnetron sputtering source 16 having a side shield assembly 46 extending therefrom, such as comprising longitudinal sides 48 and end sides 50. FIG. 6 is an end view 54 of a linear magnetron sputter deposition source 16 with an attached side shield assembly 46. FIG. 7 is a side view 60 of a linear magnetron sputter deposition source 16 having a side shield assembly 46. The rectangular sputter deposition source 16 and associated side shield assembly 46 shown in FIG. 5 have characteristic lengths 42 and widths 44, and the side shield assembly 46 has a characteristic height 52 defined from the front surface 62a of the sputter deposition source 16, and thereby typically defining a hollow interior region 49. A sputtering target 63 is typically located within and may define the front surface 62a of the sputter deposition source 16.

In some preferred embodiments of the enhanced sputtering film processing system 10, e.g. system 10b, side shields 46 are added to the linear magnetron sputter deposition sources 16, such as to improve the properties of deposited materials 74, and/or to enable the fabrication of film layers, e.g. 174, having high levels of compressive stress. As is described in detail below, systems 10 having side shields 46 have been seen to provide high quality multilayer substrates 178 (FIG. 20), whereby the side shields 46 may attenuate the amount of deposition emanating from the sputter deposition sources 16 at shallow, i.e. grazing, angles 80 relative to the amount emanating at normal 76 or off normal 78 angles.

In some embodiments of the enhanced sputtering film processing system 10, the side shields 46 comprise any of an electrically conductive material and an electrically insulating material. In some embodiments of the enhanced sputtering film processing system 10, the side shields 46 are electrically connected to a source of electrical potential selected from the group consisting of positive, negative, neutral, and ac potential. As well, in some embodiments of the enhanced sputtering film processing system 10, the side shields 46 may contain internal subdivisions having shapes selected from the group consisting of rectangles, squares, circles, polygons and combinations thereof.

FIG. 8 is an exemplary schematic view 70 of a simplified deposition pattern from a linear sputter deposition source 16 without side shields 46. FIG. 9 is an exemplary schematic view 90 of a simplified deposition pattern from a linear magnetron sputter deposition source 16 having side shields 46.

As seen in FIG. 8, as a substrate 14 moves longitudinally 72 past an exemplary sputter deposition source 16, a sputtered material 74 is deposited on the near surface 94a (FIG. 9) of the substrate 14. At the time shown in FIG. 8, the sputtered material 74 incident on the substrate 14 can be considered to be approaching as normally incident 76, off-normally incident 78, or shallowly incident 80, either fore or aft of vertical. Similarly, the sputtered material 74 at any point in time that is formed on the substrate 14 can be defined as normal incidence deposition 82, off-normal incidence deposition 84, or shallow, i.e. grazing, deposition 86.

As seen in FIG. 9, as a substrate 14 similarly moves longitudinally 72 past an exemplary sputter deposition source 16 having a side shield assembly 46, a sputtered material 74 is established on the near surface 94a of the substrate 14. At the time illustrated in FIG. 9, the sputtered material 74 incident on the substrate 14 can be considered to be approaching normally incident 76 or off-normally incident 78, either for or aft of vertical. Similarly, the deposited material 74 at any point in time that is formed on the substrate 14 can be defined as normal incidence deposition 82 and may further include off-normal incidence deposition 84, based upon the design parameters of the target 14 and shield assembly 46, and the configuration in relation to the substrate work piece 14. However, as seen in FIG. 9, the portion of the sputtering pattern 74 traveling away from sputtering deposition source 16 at angles less than indicated by trajectory 80, i.e. shallow angles, can be blocked form reaching the deposited film 92, such as through the implementation of the side shield assembly 46. The side shield assembly 46 effectively increases the relative collimation of sputter deposition target 16, by blocking at least a portion of the relatively un-collimated material 74 sputtered from the surface of sputtering deposition source 16. In some system embodiments 10, the side shields 46 extend a distance 52 (FIG. 5, FIG. 7) from the sputtering target surface 62a that is greater than the spacing between the side shield 46 and the substrate 14.

In linear transport 72, such as seen in FIG. 8 and FIG. 9, the azimuthal direction that is parallel to the substrate's transport 72 experiences a different sequence of deposition angles 73 over a pass 88 (FIG. 8) than the perpendicular direction. Moreover, in linear transport 72, a single pass 88 typically deposits 100 nm or about 300 monatomic layers (monolayers) of material 74. During such a pass 88, the incident angle 73 varies from that of grazing 80 upon the approach of the substrate 14 to the target 14 to substantially perpendicular 76 when the substrate 14 is directly in front of the sputter deposition source 16, to grazing again 80 upon the substrate's exit. Thus, the net effect of the off normal and shallow angle deposition is to reduce the level of compressive stress that can be attained.

In the exemplary systems 10a, 10b seen in FIGS. 1-4, substrates 14 are arrayed in a ring 24 on a carrier plate 12, and rotate 17 about their own axes 18 relative to the plate 12, while the ring 24 of substrates 14 and the plate 12 simultaneously rotates 26 about the plate's axis 28. The rotation 17 of the substrates 14 may preferably be at substantially the same angular velocity but with opposite sign relative to a fixed point, e.g. corresponding to a stationary sputter deposition source 16, such that the substrates 14 do not rotate relative to the fixed point.

As seen in FIG. 2 and FIG. 4, the substrates pass closely 19,34 in relation to and may be centered on each of one or more rectangular sputter deposition sources 16. Each sputter deposition source 16 in FIG. 1 and FIG. 3 is oriented with its long axis along a plate radius and with its length 42 (FIG. 5) being sufficiently longer than the substrate 14, so that the decrease in grazing-incidence deposit 80 due to proximity 32 to the end of the sputter deposition source 16 does not result in a stress nonuniformity along that direction. The length 42 of the sputter deposition source 16 is typically greater than that which is needed to achieve uniformity in film thickness.

Some preferred embodiments of the enhanced sputtered film processing system 10 use two sputter deposition sources 16, e.g. 16a and 16b, oriented at approximately at right angles to each other, so that each of the substrates 14 executes two target passes 88 during each plate 12 rotation, with each pass 88 having the substrate's 14 X and Y directions reversed relative to the pass direction. This laminates the material 74, to average out the X-Y anisotropy that is inherent to conventional linear transport 72.

The substrates 14 are preferably rotated 17 at substantially the same angular velocity but opposite sign, relative to the plate 12, as substrates 14 are rotated about a fixed point, such as to provide a uniform film thickness, whereby a point on the inner edge of each substrate 14, i.e. towards the center of the plate 12, traverses the sputter deposition source 16 at the same linear velocity as an outer point, i.e. opposite the inner point, and thus accumulates deposit for the same length of time per pass 88.

As seen in FIG. 1 and FIG. 3, the carrier plate 12 preferably comprises a ring of substrates 14 that simultaneously rotate around their own axes 18. The systems 10a, 10b seen in FIG. 1 and FIG. 3 also comprise four rectangular sputter deposition sources 16, i.e. two pairs of sputter deposition sources 16, placed at right angles to each other, to double the number of target passes 88 by each wafer 14 per plate 12 rotation. The desired orientation 22 of a wafer 14 as it passes under a rectangular sputter deposition source 16 is also shown in FIG. 1 and FIG. 3. For this example, the wafer 14 rotates by about 90 degrees to have the identical orientation 22 under each sputter deposition source 16, relative to a fixed point.

While the exemplary systems 10a and 10b seen in FIG. 1 and FIG. 3 respectively comprise four sputter deposition sources 16, alternate system embodiments 10 may comprise a different number of sputter deposition sources 16. For example, six or even twelve sputter deposition sources 16 may be provided, oriented at about 90 degrees to a next sputter deposition source 16, such as in a circle above or below the plate 12 to accommodate source pairs 16 for depositing any of adhesion layers, release layers, and/or spring metal layers as well as duplicates of each sputter deposition source 16 to increase the throughput and/or extend the time between source 16 replacement.

In some system embodiments 10, an ion source 20 may be located at a point around the plate 12, to bombard the film with ions 33 and thereby impart compressive stress when desired or perform a sputter etching or cleaning process. FIGS. 1-4 show an exemplary location of the ion source 20. The substrates 14 can alternately be electrically biased with DC power if conductive, or RF power if insulating, to accelerate the bombarding ions out of the plasma generated by the sputter deposition source 16, without the use of an ion gun 20. In some system embodiments 10, one or more ion guns 20 are provided for any of sputter etching and surface cleaning for the substrates 14 or formed layers thereon, e.g. 172, 174 (FIG. 24, FIG. 25).

Over the course of a single rotation of plate 12, each substrate 14 experiences periodic variation in several process parameters that affect stress, e.g. deposition angle of incidence and azimuthal orientation to the target's longitudinal axis 47 (FIG. 5). In system embodiments 10 in which it is preferred that such variations do not result in a periodic layering of film stress, the period of this variation in terms of equivalent film thickness should be of the order of a few atomic spacings, so that the developing atomic structure does not exhibit a variation.

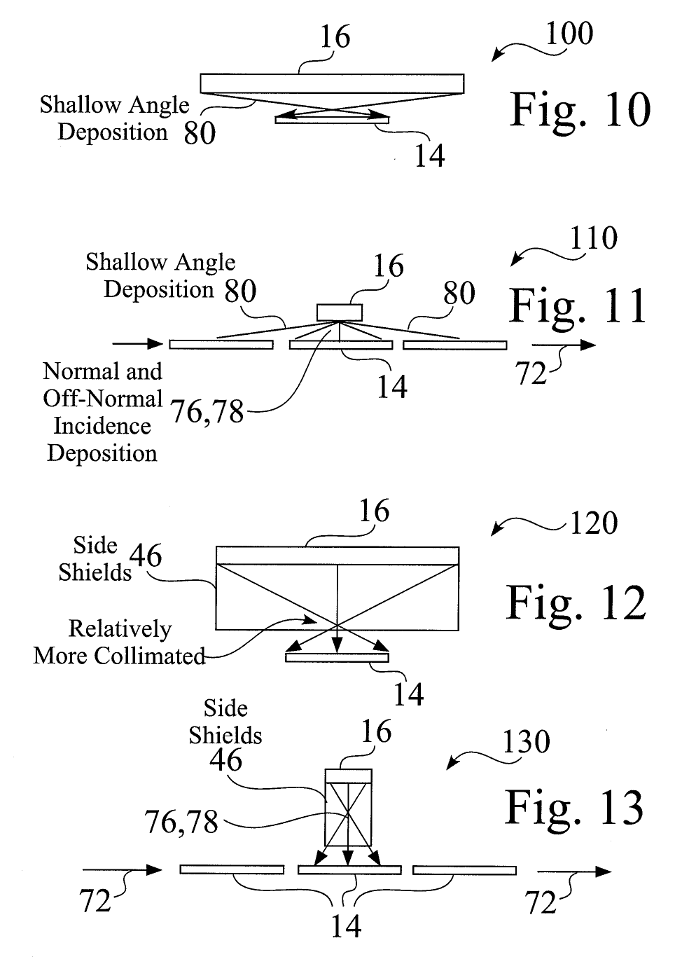

FIG. 10 is schematic front view 100 of a magnetron sputter deposition sources 16 without a side shield 46, having shallow, i.e. grazing angle, incidence deposition 80 from the ends of the sputter deposition source 16 as a substrate 14 passes by the sputter deposition source 16. FIG. 11 is an end view 110 of a magnetron sputter deposition source 16 without a side shield 46, having shallow, i.e. grazing, angle incidence deposition 80 from the ends of the sputter deposition source 16 as substrates 14 pass 72 by the sputter deposition source 16. The absence of side shields 16 and the presence of shallow angle deposition in both FIG. 10 and FIG. 11 is characteristic of a relatively un-collimated deposition source 16.

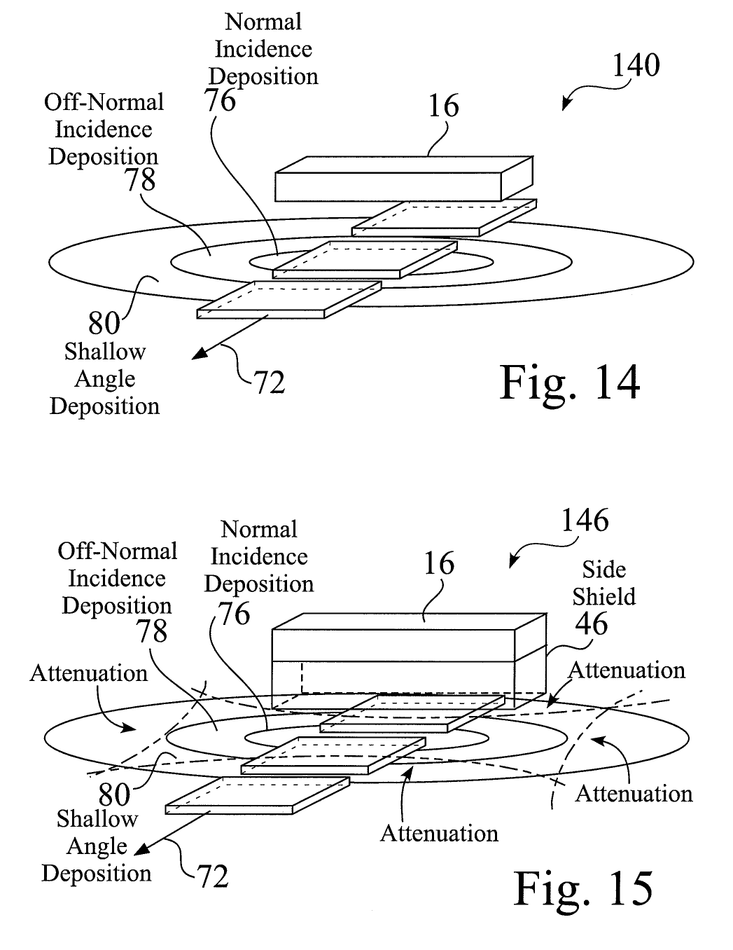

FIG. 12 is a front view 120 of a magnetron sputter deposition source 16 with one or more side shields 46, showing steeper angle of incidence deposition from the ends of the target 16 as a substrate 14 passes by the sputter deposition source 16, due to increased distance of the sputter deposition source 16 from the substrate 14. FIG. 13 is an end view 130 of a magnetron sputter deposition source 16 with one or more side shields 46 showing attenuated shallow incidence deposition and steeper off-normal incidence deposition 78 from the length of the sputter deposition source 16. The side shields 16 effectively increase the relative degree of collimation for the sputter deposition source 16 shown in FIG. 13 and FIG. 14.

The relative increase in deposition in the near normal angle range also results in an increase the average energy of the depositing atoms. Experimental data provided below indicate that such effects may combine to produce layers having a crystallographic structure that is consistent with inherent compressive stress when the sputter sources are operated at low deposition pressures.

FIG. 14 is a simplified perspective view 140 of a deposition pattern from a linear magnetron sputter deposition source 16 without side shields 46. FIG. 15 is a simplified perspective view 146 showing an exemplary attenuated deposition pattern from a linear magnetron sputter deposition source 16 having side shields 46.

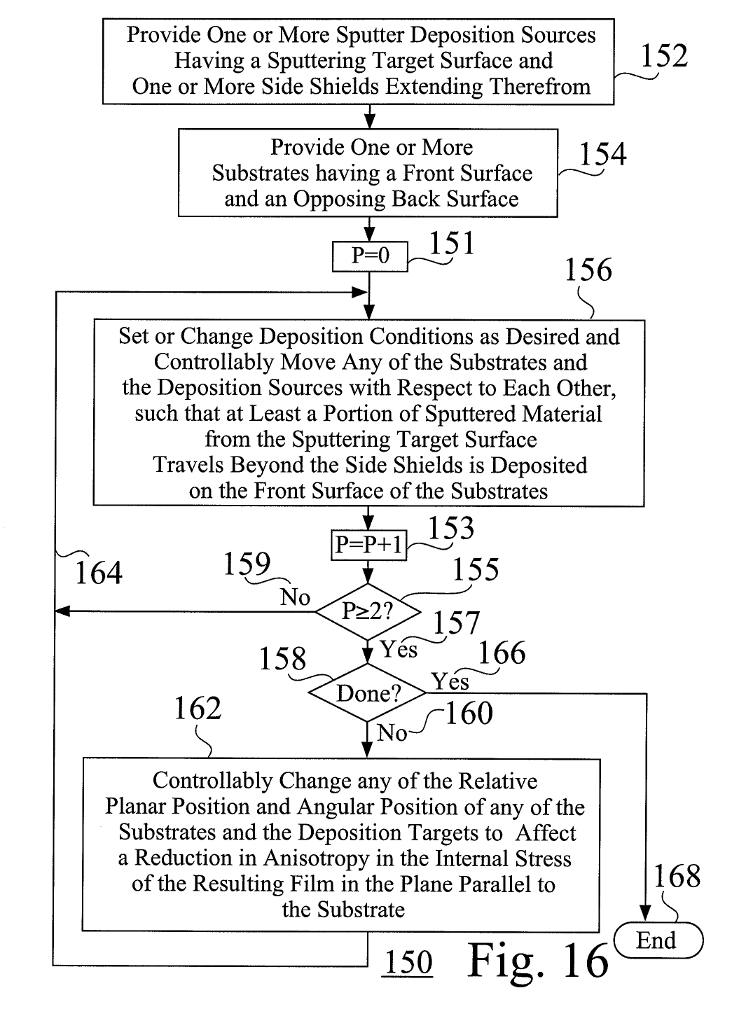

FIG. 16 is a flowchart of an exemplary enhanced sputtering process 150. At step 152, one or more deposition sputter deposition sources 16 are provided, each having a sputtering target surface 62a (FIG. 7) and one or more side shields extending from the sputter deposition sources 16, such as about the periphery of the sputtering target surface 62a. At step 154, one or more substrates, i.e. workpieces 14 are provided, wherein the substrates 14 have a front surface 94a (FIG. 9) and an opposing back surface 94b (FIG. 9), and may have one or more previously applied layers, e.g. such as an adhesion layer 172.

In some embodiments of the enhanced sputtered film processing system 10 and method 150, the adhesion layer 172 may comprise one or more layers having an inherent level of stress fabricated from a chemically dissolvable material, such as comprising a material selected from the group consisting of titanium, chromium, nitride and combinations thereof.

At exemplary step 151, a counter P may be initialized in association with a number of deposited layers. At step 156, the substrates 14 and the sputter deposition sources 16 are controllably moved with respect to each other, such that at least a portion of the material sputtered from the sputtering target surface 62a travels beyond the side shields 46 and is deposited on the front surface 94a of the substrates 14.

As seen at step 153, the counter P is incremented to reflect the deposited layer from step 156. A decision step 155 may be made to determine if two or more layers, e.g. 174, have been deposited. If not 159, the process typically returns 164 to step 156 for further controlled deposition. If two or more layers, e.g. 174, have 157 been deposited, and if the number of desired passes 88 is determined 158 to be completed, e.g. two or more layers as desired for the fabrication of any of layers having isotropic internal stress, stress gradients in the direction normal to the substrate, and the construction of at least one photolithographically patterned spring 246 (FIG. 26), the process 150 is ended 168. If the process 150 is not done 160, any of the relative planar position and/or angular position of any of the substrates 14 and the sputter deposition sources 16 is controlled, at step 162, and returns 164 to step 156 for further controlled deposition.

As seen at exemplary step 162 in FIG. 16, any of the relative planar position and/or angular position of any of the substrates 14 and the sputter deposition sources 16 is typically controllably changed to affect a reduction in the anisotropic stress field in the plane parallel to the substrate 14 between the next deposited film layer, e.g. 174, and at least one other layer.

In some embodiments of the enhanced sputtered film processing process 150, such as seen in the exemplary method 150 of FIG. 16, the initial sputtering pressure can be set and/or and changed at any point during the process. For example, the pressure can be regulated to a predetermined value prior to the first deposition 156, held constant for a pre-determined number of passes under the sputter deposition sources 16 to produce a resulting layer 174 with reduced anisotropy, and changed to a new pressure value, such as under computer and/or local control for a succession of layers 174, to produce a stress gradient.

The enhanced sputtered film processing system 10 and method 150 provides sputtered films that are controllably uniform and/or isotropic. In an embodiment of the enhanced sputtered film processing system 10, the sputtering source configuration geometry allows the fabrication of films with uniform thickness having inherent internal stresses ranging from compressive to neutral to tensile while minimizing X-Y stress anisotropy, i.e. stress non-uniformity across the substrate, where the X-Y refers to two orthogonal dimensions, e.g. 25,27 (FIG. 1), parallel to the plane of the substrate 14.

Desired levels of film stress, ranging from highly compressive to highly tensile, can be achieved by varying sputter deposition conditions such as the deposition gas pressure. In some embodiments of the enhanced sputtered film processing system 10 and method 150, one or more sputter deposition conditions are controlled such that the one or more layer 174 is formed with a controllable internal stress in a plane parallel to the substrates 14 up to the maximum internal stress that the spring material can sustain.

An exemplary method for controlling gas pressure comprises controllably admitting an inert gas, e.g. Argon, into the vacuum chamber 15 (FIG. 1) associated with the system 10, providing a vacuum pump capable of removing the admitted gas from the vacuum chamber 15, and providing a throttle valve located within the vacuum chamber 15 and between the gas source and the vacuum pump. Initially, the throttle valve is positioned to a convenient point in its operating range, e.g. approximately in the center of its range, and the admitted gas flow rate is set to a level that is consistent with the capacity of the vacuum pump. The throttle valve is adjustable to cause the pressure of the admitted gas within the vacuum chamber 15 to increase or decrease. The system 10 may preferably comprise closed loop feedback, such as to provide real time readout of the pressure in the vacuum chamber 15, e.g. using an electronic pressure transducer, and interfacing the signal from the pressure transducer to a computer to compare the real time pressure to a pre-determined set point and then automatically adjusting either the position of the throttle valve to regulate the pressure within the vacuum chamber 15 prior to initiating deposition cycle 156. The pressure can be regulated to a single value or to a series of values at desired times during deposition cycle 156, or 162.

Those skilled in the art will recognize that the function of the present system and method embodiments 10, 150 are not limited to the specific example presented above for controlling gas pressure within a vacuum chamber 15. Other equivalent means for controlling deposition may be substituted for use with the enhanced sputtered film processing system 10 and associated method 150 described herein.

If the number of desired passes is determined to be complete, the process 150 is ended 168. If the process 150 is not done, the relative planar position and angular rotation of any of the substrates and the deposition sources may be controllably changed 162, and the process 156 is repeated for further controlled deposition.

The enhanced sputtered film processing system 10 and associated method 150 can be used to fabricate a resulting film with substantially uniform thickness and isotropic stress by laminating two or more thin film layers deposited on a substrate 14. The method comprises moving the sputter deposition sources and the substrates with respect to each other in a predetermined manner during the deposition of each of the two or more thin film layers such that any X-Y anisotropy in stress in each of the two or more thin film layers (in the plane parallel to the substrate), arising from X-Y anisotropy in the deposition angle from the at least one deposition source, is averaged out.

An exemplary enhanced sputtered film processing system 10 and associated method 150 provides at least two rectangular sputter deposition sources 16, one or more substrates 14, a drive mechanism 13 (FIG. 1) to impart planetary motion to the substrates 14 such that the orientation of the one or more substrates 14 relative to each of the at least two deposition sources 16 remains constant as the one or more substrates 14 travels about its orbit and is located centrally when passing the at least two deposition sources 14 such that any X-Y anisotropy in stress in each of two or more thin film layers (in the plane parallel to the substrate), arising from X-Y anisotropy in the deposition angle from the at least two deposition sources 16, is averaged out.

The laminated films having substantially uniform thickness and isotropic stress fabricated using the enhanced sputtered film processing method can be combined to create a stress gradient in a composite film deposited on a substrate. The method comprises fabricating two or more laminated films each having a substantially uniform thickness and predetermined value of isotropic stress, e.g. compressive, neutral, or tensile, in the plane parallel to the substrate such that the resulting composite film comprises a stress gradient in the direction normal to the substrate, e.g. a stress gradient ranging from compressive to neutral to tensile. In some embodiments, the stresses in the plurality of layers range from compressive to tensile. In other embodiments, the stresses in the plurality of layers range from tensile to compressive. As well, in some embodiments, stresses in the plurality of layers may include any combination of controlled transitions between any of compressive, neutral, or tensile isotropic stress.

For embodiments of the process 150 which are used to produce composite multilayer springs 264, the layers 174 may preferably be fabricated from an elastic material such as a metal comprising any of MoCr, Tungsten, Tantalum and/or any combination thereof.

FIG. 17 is a simplified schematic diagram that illustrates deposition of a material 174a, e.g. to form a MoCr layer 174a, on an adhesion layer 172, e.g. titanium, formed on a front surface 94a of a substrate 14 moving longitudinally in relation to a magnetron sputter deposition source 16 having a side shield 46. The deposition 174a shown comprises normal 76 and off-normal 78 incidence components, while the side shield attenuates shallow i.e. grazing, angle deposition 80.

FIG. 18 shows 178 a deposited layer 174a having internal stress (e.g. compressive) on an adhesion layer 172. The deposited layer 174a typically has a level of compressive stress that represents the relative contributions of normal and off-normal incidence deposition components, and the stress field is symmetrical but non-isotropic.

FIG. 19 shows the formation 186, similar to the first pass 88 seen in FIG. 17, of a second deposited layer 174b upon the prior deposited layer 174b, on the substrate 14 which has been rotated 90 degrees, as indicated by an orientation marker 176. FIG. 20 shows the resultant composite deposition layer 178, i.e. comprising two or more layers 174, e.g. 174a,174b on an adhesion layer 172 after two deposition passes 88. The resultant composite deposition layer 178 has a uniform and isotropic compressive stress when a stress gradient is established in the completed film, between multiple deposition layers 174.

In reference to the FIG. 16 and FIGS. 17-20, some embodiments of the enhanced sputtered film processing system 10 and method 150 create a composite deposition layer 178 on a substrate 14, by depositing successive layers 174 on the substrate 14 at any of successive different discrete deposition angles of rotation of the substrate 14 and/or of the deposition source about a normal axis of the substrate 14.

The enhanced sputtered film processing system 10 and method 150 may preferably provide a substantially identical amount of deposition from each different deposition angle as for each other deposition angle, wherein the overall deposited film behaves substantially isotropically in properties, e.g. such as mechanical, electrical, and optical properties, in all directions parallel to the substrate 14 and at different angles of rotation about the normal axis 18 (FIG. 1, FIG. 3).

Some embodiments of the enhanced sputtered film processing system 10 and method 150 preferably comprise moving each substrate 14 past a same one or more sputter deposition sources 16 of depositing material in a planetary manner, wherein each time the substrate 14 passes by one of the sputter deposition sources 16 of depositing material as the substrate 14 executes a planetary orbit, the substrate 14 has been rotated about the substrate's normal axis 18 with respect to the sputter deposition source 16 by which the substrate 14 is passing.

In one embodiment, one or more substrates 14 are preferably rotated about 360/n degrees each time the substrates 14 passes by one of n the sputter deposition sources 16, wherein n is an integer larger than 2, or preferably by about 90 degrees if n is 2.

Some embodiments of the enhanced sputtered film processing system 10 and method 150 preferably comprise providing two or more sputter deposition sources 16 arranged about a circle 24, as seen in FIG. 1 and FIG. 3, and positioning a relevant anisotropic property of each the sputter deposition source 16 about 90 degrees with respect to that of a previous sputter deposition source 16, wherein each substrate 14 preferably maintains a fixed rotational orientation about its normal axis 18 as the substrate 14 orbits, as measured from a stationary point; wherein the material 74 is deposited in layers 164, e.g. 164a,164b (FIG. 16), having an anisotropy rotated by about 90 degrees for each successive layer 164.

In one system embodiment 10, the source 16 of depositing material exhibits two-fold symmetry in a relevant anisotropic property of the depositing material source. In one system embodiment 10, a substrate rotation of about 270 degrees is equivalent to a substrate rotation of about 90 degree with respect to the anisotropy in the relevant property of the film layer when the source 16 exhibits two-fold symmetry.

Some embodiments of the enhanced sputtered film processing system 10 and method 150 preferably comprise providing two or more sputter deposition sources 16, wherein each sputter deposition source 16 has two-fold symmetry, wherein the sputter deposition sources 16 are disposed relative to one another such that a relevant anisotropic property of a sputter deposition source 16 is rotated by a pre-set angle with respect to a previous sputter deposition source 16, wherein each substrate 16 maintains a fixed rotational orientation about its normal axis 18 as it orbits, as measured from a stationary point; and wherein the film is deposited in layers 174, e.g. 174a,174b, having an anisotropy rotated by the preset angle for each successive layer 174.

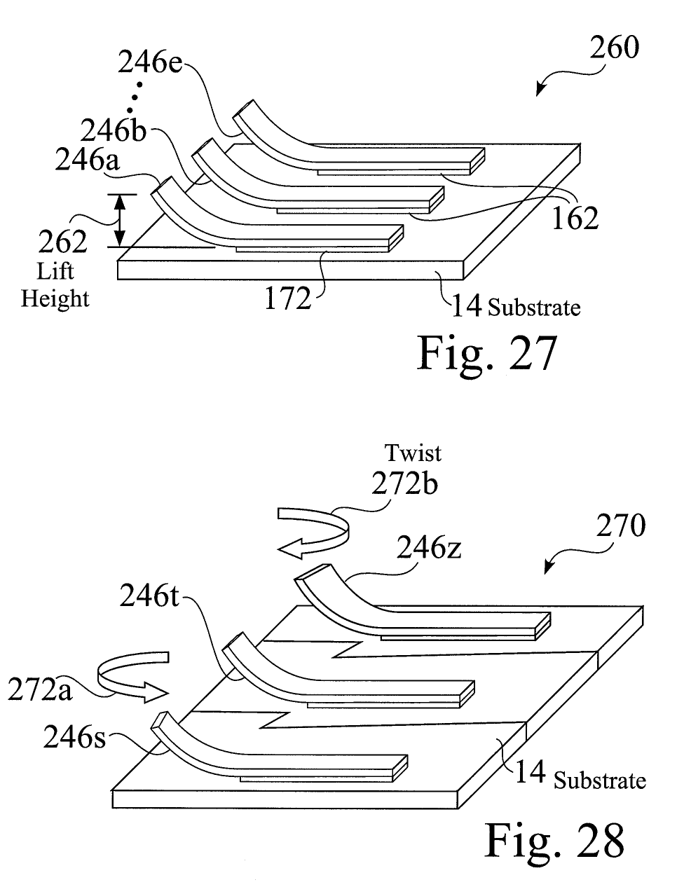

In some embodiments of the enhanced sputtered film processing system 10 and method 150, the pre-set angle ranges from about 45 to about 135 degrees. In alternate embodiments of the enhanced sputtered film processing system 10 and method 150, the pre-set angle ranges from about 80 to about 100 degrees. In another embodiment, the pre set angle is about 90 degrees. In another embodiment, the pre set angle is 90 degrees. In another embodiment, the pre set angle is determined by experiment to optimize the properties of the material 74 and one or more layers 174, e.g. to minimize stress variations or spring lift height 262 (FIG. 27) over the surface of the substrate 14.

In some embodiments of the enhanced sputtered film processing system 10 and method 150, the sputter deposition sources 16 of depositing material comprise linear magnetron sputter deposition sources 16 from which the depositing material emanates in a pattern that approximates a rectangle having rounded corners. Each such sputter deposition source 16 is preferably equipped with a side shield 46 that extends 48 along at least a portion of each of the long sides of each sputter deposition source 16, and may also extend along at least a portion 50 of the ends of each sputter deposition source 16.

In some embodiments of the enhanced sputtered film processing system 10 and method 150, the distance from the sputtering target surface 62a to the edge of the side shield 46 is greater than the distance from the substrate 14 to the edge of the side shield 46. In a second embodiment, the distance from the sputtering target surface 62a to the edge of the side shield 46 is about three times the distance from the substrate 14 to the edge of the side shield 46.

In some alternate embodiments of the enhanced sputtered film processing system 10 and method 150, the distance from the sputtering target surface 62a to the edge of the side shield 46 is optimized by experiment. For example, at a given distance 35 between the substrate surface 94a and the edge of the side shield 46 which is preferably minimized and determined, such as subject to geometrical system constraints, the distance from the sputtering target surface 62a to the edge of the side shield 46 may be experimentally optimized to yield films with desired properties and high mechanical integrity, such as but not limited to any of:
stress uniformity and isotropy in and/or orthogonal to the plane of the substrate 14 within each layer of the film;
durability;
resistance to set
lack of failure inducing defects;
uniform crystallographic properties or atomic structure;
uniform grain properties; and
thickness uniformity.

Sputter deposition sources 16 equipped with side shields 46 have been demonstrated to be capable of depositing layers of materials such as MoCr films with ranges of inherent compressive stress without the use of a secondary ion gun 20. Stress levels have been achieved ranging from in excess of about −1.5 GPa compressive to in excess of about +1.5 GPa tensile without an ion gun as the pressure of the working gas in the deposition chamber is varied from about 1 milli Torr to about 15 milli Torr.

Sputter deposition sources 16 equipped with side shields 46 have also been demonstrated to be capable of depositing layers of materials such as titanium with inherent compressive stress without the use of a secondary ion gun 120. Stress levels have been achieved ranging from in excess of about −0.5 GPa compressive to in excess of about +0.2 GPa tensile as the pressure of the working gas in the deposition chamber is varied from about 2 milli Torr to about 10 milli Torr.

Dual magnetron sputter deposition sources 16 equipped with side shields 46 have been demonstrated to be capable of depositing materials such as MoCr films 174 and titanium films 172 with improved uniformity and isotropy over larger substrate areas compared to single magnetron sputter deposition sources 16 or dual magnetron sputter deposition sources 16 not equipped with side shields 46.

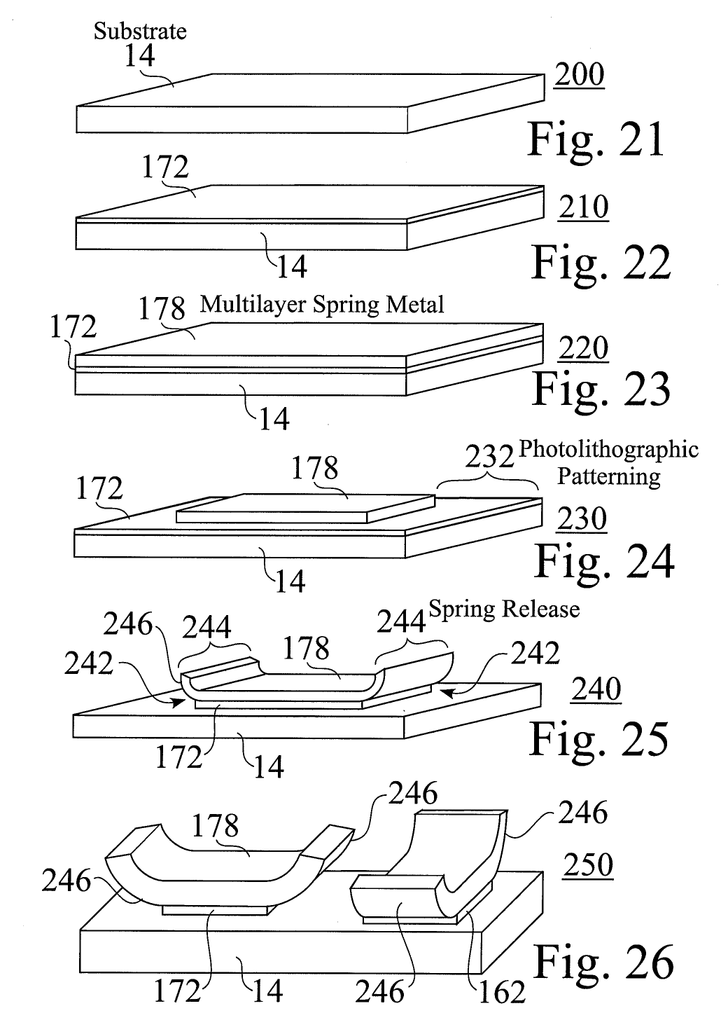

FIG. 21 through FIG. 26 illustrate a sequence of process steps for the fabrication of pholithographically patterned springs 246, e.g. such as composite layer 178 MoCr springs 246, which may preferably be formed with uniform and isotropic properties, e.g. uniform lift height and no twist regardless of orientation, on an adhesion layer 162, e.g. comprising titanium. In some embodiments, the springs 246 are comprised of spring materials that can maintain stress over initial process temperatures, e.g. 300-400 degrees C., as well as over subsequent operating temperatures, e.g. typically about 200 degrees C.

FIG. 21 is a perspective view 200 of a base substrate 14 to be used for the fabrication of pholithographically patterned springs 246 (FIG. 26). FIG. 22 shows an adhesion layer 172 formed 210 on a base substrate 14, such as through use of the deposition system 10, e.g. 10a, 10b. In some embodiments, the front surface 94a of the substrate 14 may be sputter cleaned prior to deposition 210 of the adhesion film layer 172. In some embodiments, a first primary layer 172, e.g. adhesion layer 172a, may be sputter cleaned prior to deposition of a subsequent primary layer 172, e.g. a release layer 172b.

The adhesion layer 172 may itself comprise one or more layers 172 having an inherent level of stress. An adhesion layer 172 provides adhesion between the substrate 14 and subsequently deposited film layers 174. In some embodiments, the fabricated adhesion layer 172 comprises any of titanium, chromium, nitride and/or any combination thereof.

FIG. 23 shows the formation 220 of a multilayer spring metal film 178 on an adhesion layer 172, as seen in detail in FIGS. 17-20. In some embodiments, the primary layer 172, e.g. the adhesion or release layer 172a, may be sputter cleaned prior to deposition 170 of a spring metal film layer 174, e.g. 174a.

FIG. 24 is a basic schematic view 230 of photolithographic patterning 232 on the multiplayer spring metal film 178 located on an adhesion layer 172. FIG. 25 shows 240 the result of photolithographic patterning 232 and selective removal 242 of a portion of the adhesion layer 172, such as by selective etching of the adhesion layer 172, wherein spring tips 246 are lifted 244 away from the substrate 14. FIG. 26 is a schematic depiction of resultant stress metal springs 246 having different orientations with respect to a support substrate, and having uniform lift without twist 272 (FIG. 27).

The exemplary monolithic micro-fabricated spring contacts 246 comprise stress metal springs that are photolithographically patterned and fabricated on a substrate 14 using batch mode semiconductor manufacturing processes. As a result, the spring contacts 264 are fabricated en masse, and can be fabricated with spacings equal to or less than that of semiconductor bonding pads or with spacings equal to or greater than those of printed circuit boards, i.e. functioning as an electrical signal space transformer.

Monolithic micro-fabricated spring contacts 264, such as seen in FIG. 26, comprise a unitary, i.e. integral construction or initially fabricated using planar semiconductor processing methods, whereas non-monolithic spring contacts are typically assembled from separate pieces, elements, or components. The monolithic micro-fabricated spring contacts 264 can be fabricated on one or both sides of rigid or flexible contactor substrates 14, which may further comprise electrically conductive through-vias and multiple electrical signal routing layers on each side of the substrate 14 to provide electrically conductive paths for electrical signals running from spring contacts 264 on one side of the substrate 14 to spring contacts or other forms of electrical connection points on the opposite side of the substrate 14 through signal routing layers on each side of the substrate 14 and one or more electrically conductive vias fabricated through the substrate 14.

Additionally, optical signals can be transmitted through the resultant substrate 14 by fabricating openings of sufficient size through the substrate 14 through which the optical signals can be transmitted. The holes may be unfilled or filled with optically conducting materials including but not limited to polymers, glasses, air, vacuum, etc. Lenses, diffraction gratings and other optical elements can be integrated to improve the coupling efficiency or provide frequency discrimination when desired.

In some embodiments, the stress metal springs 264 may preferably be fabricated by sputter depositing a titanium adhesion/release layer 172 having a thickness of 1,000 to 5,000 angstrom on a ceramic or silicon substrate 14 (approximately 10-40 mils thick) having a diameter ranging from about 1 millimeter to about 1 meter, which may further comprise electrically conductive vias pre-fabricated in the substrate 14 having diameters of 1-10 mils. Electrically conductive traces fabricated with conventional photolithographic processes connect the spring contacts to such conductive vias and to the circuits to which they may ultimately connect. A common material used to fabricate stress metal springs is MoCr, however other metals with similar characteristics, e.g. elements or alloys, may be used. An exemplary stress metal spring contact is formed by depositing a MoCr film in the range of 1-5 μm thick with a built-in internal stress gradient of about 1-5 GPa/μm. An exemplary MoCr film is fabricated by depositing 2-10 layers 174 of MoCr, each layer 174 about 0.2-1.0 μm thick. Each layer 174 is deposited with varying levels of internal stress ranging from up to 1.5 GPa compressive to up to 2 GPa tensile.

Individual micro-fabricated stress metal spring contact fingers 264 are photolithographically patterned and released from the substrate 14, using an etchant to dissolve the release layer 162. The sheet resistance of the finger 264 can be reduced by electroplating with a conductive metal layer (such as copper or gold). The force generated by the spring contact 264 can be increased by electrodepositing a layer of a material, such as nickel, on the finger 264 to increase the spring constant of the finger 264. In interposer applications, the quality of the electrical contact 264 can be improved by electrodepositing depositing a material, such as rhodium, onto the tip 264 through a photomask, prior to releasing 244 the finger 264 from the substrate 14.

The lift height 262 (FIG. 27) of the spring contacts 246 is a function of the thickness and length of the spring 246 and the magnitude of the stress gradient within the spring 246. The lift height 262 is secondarily a function of the stress anisotropy and the width of the spring 246 and the crystal structure and stress in the underlying stress metal film release layer 172. The spring constant of the spring 246 is a function of the Young's Modulus of the material used to fabricate the spring 246 and the length, width, and thickness of the spring 246. The spring constant of the spring 246 can be increased by enveloping the springs 246 with a coating of a metal including but not limited to electroplated, or sputtered, or CVD deposited nickel or a nickel alloy, gold, or a palladium alloy such as palladium cobalt.

Some embodiments of the method 150 and system 10 comprise processes for fabricating spring contacts having properties with predictable errors and methods for compensation and reduction of errors in subsequently fabricated spring contact properties, e.g. lift heights and tip positions.

An exemplary method for compensation and reduction of the errors in spring contact properties comprises the steps of: fabricating a first device on a first substrate comprising at least one spring contact, measuring the errors in the properties of the at least at least one spring contact in the first device, modifying the fabrication processes such as to reduce the errors in the properties of subsequently fabricated devices. The measurable properties comprise any of spring contact length, width, shape, angular orientation, tip height and tip position.

An exemplary process for fabricating spring contacts comprises the steps of fabricating a first calibration spring array of photolithographically patterned springs on a substrate, each member of the calibration spring array being positionally distributed over a designated area of the substrate, at least one photomask used in fabricating the calibration spring array such as to define any of the length, width, shape, angular orientation, and position of each spring in the calibration spring array; measuring the errors in any of the length, width, shape, angular orientation, position, spring lift height, and tip position of each member of the fabricated calibration spring array and determining an error correction matrix for each member or the calibration spring array; and compensating a second device spring array for any errors in any of the length, width, shape, angular orientation, position, spring lift height, and tip position in the vicinity of each member of the fabricated calibration spring array using the correction matrix to adjust the photolithographic pattern on at least one photomask used to fabricate the device spring array such as by changing any of the length, width, shape, angular orientation, and position of the each member of the device spring array relative to the substrate to reduce any errors in spring lift height and tip position of any of the one or more photolithographically patterned springs in the device.

FIG. 27 is an exemplary schematic view 260 of pholithographically patterned multilayer springs 246, having a characteristic spring height 262, as fabricated from multiple film layers 164, e.g. 164a-164n, and having uniform and isotropic levels of stress. FIG. 28 is an exemplary schematic view 270 of pholithographically patterned multilayer springs fabricated from multiple film layers 174, e.g. 174a-174n, and having uniform and non-isotropic levels of stress, which may result in a twist 272, e.g. 272a, 272b, of the formed non-planar springs 246.

It has been determined experimentally that photolithographically patterned MoCr springs 246 exhibit higher lift heights 262 when fabricated on titanium release films 162 deposited at lower pressures using dual magnetron sputter deposition sources 16 equipped with side shields 46.

Differences have been observed in resultant lift height 262 and twist 272, e.g. 272a,272b of photolithographically patterned MoCr springs 246 that are fabricated on top of titanium release films 162. For example, MoCr springs 246 have been observed to exhibit increased lift height 262 when fabricated on top of titanium release films 162 that are fabricated at lower deposition pressures. Films comprised of materials such as titanium deposited at low pressures may have crystallographic structures, grain sizes and/or orientations that may differ from such films deposited at higher pressures.

In some embodiments of the enhanced sputtered film processing system 10 and method 150, a distance along a substrate normal axis 18 and between a substrate surface 94a and a target surface 62a from which depositing material 74 emanates is sufficiently smaller than a distance between material as it emanates from an end of the rectangular emanation pattern and a nearest edge of the substrate 14, such that a relevant property of the sputtered material 74 is sufficiently uniform along the substrate 14 from a center of the substrate 14 to the substrate's edge.

Some embodiments of the enhanced sputtered film processing system 10 and method 150 comprise a symmetrical disposition at least one sputter deposition source 16 having a side shield 46 at any of successive different deposition angles of rotation of the substrate 14 and/or of the sputter deposition source 16 about a normal axis 18 of the substrate 14, and deposition of successive layers 174, e.g. 174a, 174b on the substrate 14, such as to achieve high levels of stress in the film layers 174, wherein the stress is both isotropic in a film plane and uniform over large areas of a substrate surface 94a.

Some embodiments of the enhanced sputtered film processing system 10 and method 150 preferably provide a single or a multi-atomic-layer-scale deposition thickness 182 (FIG. 18) per pass 88 over a target using magnetron sputtering using substantially rectangular sputter deposition sources 16, such as to reduce effects on film stress that may be caused by periodic fluctuations in any of deposition incident angle, ion bombardment flux, and substrate azimuthal orientation. The number of monoatomic layers may preferably be varied from less than 1 to about 100. The rotation rate of the substrates 14 in relation to the sputtering targets 16 may preferably be reduced in proportion to the number of number of monolayers deposited in a single pass 88.

In some embodiments of the enhanced sputtered film processing system 10 and method 150, the substrates 14 are rotated by about 90 degrees relative to the sputter deposition source 16 over which it is passing between successive passes 88 to laminate the film 174, such as to minimize X-Y anisotropy in a film plane.

Some embodiments of the enhanced sputtered film processing system 10 and method 150 comprise using magnetron sputter deposition sources 14 that are longer, when compared to a substrate diameter, than is needed for uniform film thickness; wherein film stress non-uniformity along a longitudinal axis 47 of the source 16 is minimized.

In some embodiments of the enhanced sputtered film processing system 10, e.g. 10a (FIG. 1), 10b (FIG. 3) and method 150, the ring 24 of substrates 14 are each rotated 17 about their central axes 18, such as by a substrate drive means 13 (FIG. 1, FIG. 3), while the ring 24 of substrates 14 is rotated, i.e. as a group, such as by drive means 11 (FIG. 1, FIG. 3), around a central axis 28 of the apparatus 10, to impart high speed, planetary motion to the substrates 14. In some embodiments of the enhanced sputtered film processing system 10, e.g. 10a (FIG. 1), 10b (FIG. 3) and method 150, the system drive means 11 and the substrate drive means 13 comprise a single linked system, e.g. such as but not limited a drive motor with a mechanical link to provide system rotation 11, and a secondary mechanical link to provide substrate rotation 13.

The substrates 14 can be either round, e.g. less than or equal to 100 mm diameter or greater that 100 mm, or square, e.g. less than or equal to 100 mm on a side, or greater than 100 mm on a side. Other embodiments could utilize substrates of other shapes and sizes as well.

In some embodiments of the enhanced sputtered film processing system 10 and method 150, the substrates 14 may comprise any of ceramic, silicon, glass, glass ceramic, diamond, FR4 or other printed circuit board, a polymer, e.g. polyimide, and/or any combination thereof.

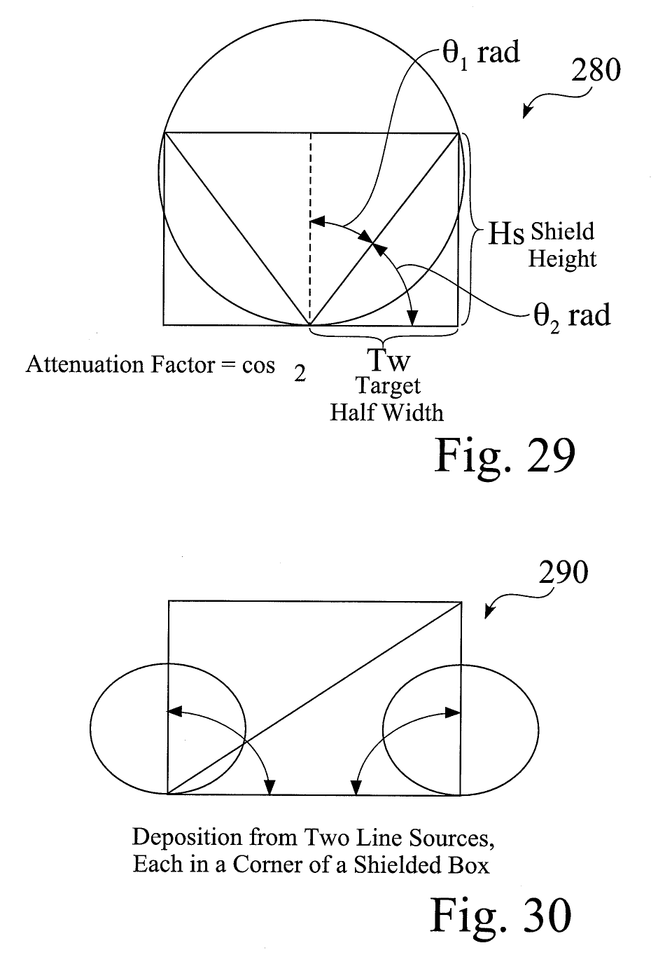

FIG. 29 illustrates a method 280 for modeling the change in deposition pattern due to the addition of side shields 46 from an idealized “single line” sputter deposition source 16 placed in the center of the source 16. The sputter deposition source 16 has an angular deposition dependency that is approximated by a cosine function.

FIG. 30 illustrates a method 290 for modeling the change in deposition pattern due to the addition of side shields 46 from an idealized double line sputter deposition source 16 placed in the corners of a rectangular, i.e. box, shape formed by the actual sputter deposition source 16 and the side shields 46. The sputter deposition sources 16 have angular deposition dependences approximated by a cosine function.

Functional Embodiment. An exemplary embodiment of the system 10 was installed in a conventional 10-7 Torr stainless-steel or aluminum high-vacuum chamber with elastomer seals and cryopumping, such as manufactured by Leybold and other vendors.

The exemplary system 10b comprised at least two rectangular magnetron sputter sources 16, such as those manufactured by Leybold, and an ion gun 20 with a 6-inch diameter beam, such as a Kaufman-style gun, as manufactured by Commonwealth, and arranged as seen in FIG. 3 and FIG. 4. The cathodes were oriented approximately 90 degrees to each other. The perpendicular distance from the magnetron target surface 62a of the sputter deposition sources 16 to the wafers 14 was typically set to about 9 cm. The width of the side shield 46 for the exemplary system 10b was 6.5 cm and the distance 35 from the edge of the side shield 46 to the substrate 14 was about 2.5 cm.

The planetary linkage for wafer motion is connected so that the wafers 14 remain in the same rotational orientation about their own normal axes 18 relative to a fixed point as they orbit about the central axis 28 of the chamber.

The exemplary plate 12 rotating about the central axis 28 carries 6″ wafers on a 10-inch orbiting radius from the center of the plate 12, and the 14-inch long magnetron sputter deposition sources 16 and the ion gun are centered on the wafers 14. Fixturing is arranged so that the wafers 14 are exposed to an even angular distribution and flux of depositing material across their surface 94a.

Calibration Process. As discussed above, the enhanced sputter deposition system 10 may preferably be optimized based upon experimental calibration of operating parameters.

Calibration step 1. Film stress vs. pressure of an Ar sputtering gas is measured by sputter deposition at various fixed pressures onto thin wafers. The stress is then calculated in a conventional manner by means of the change in curvature of the wafer caused by the deposition.

Calibration step 2. Deposition of a multilayer structure is carried out using a progression from compressive to tensile stress along the positive-slope portion of the stress-pressure curve. Springs are patterned and lifted, and spring curvature radius is calculated from lift height.

Typical Parameters. Typical operating parameters used for deposition in some current embodiments of the system 10 are as follows (ranges are shown in brackets):

MoCr alloy target, typ. 0-20 at. % Cr: power 2400 W (500-10,000), gas flow: Ar 80 sccm (10-500), pressure: 0.6 to 15 mT (0.2-50), plate rotation rate: 30 rpm (1-240).

Ion Gun: beam current from 50 to 500 mA, ion energy from 200 to 1000 eV.

System Performance. System performance was tested and measured over a variety of operating parameters for different embodiments of the enhanced sputtering system 10.

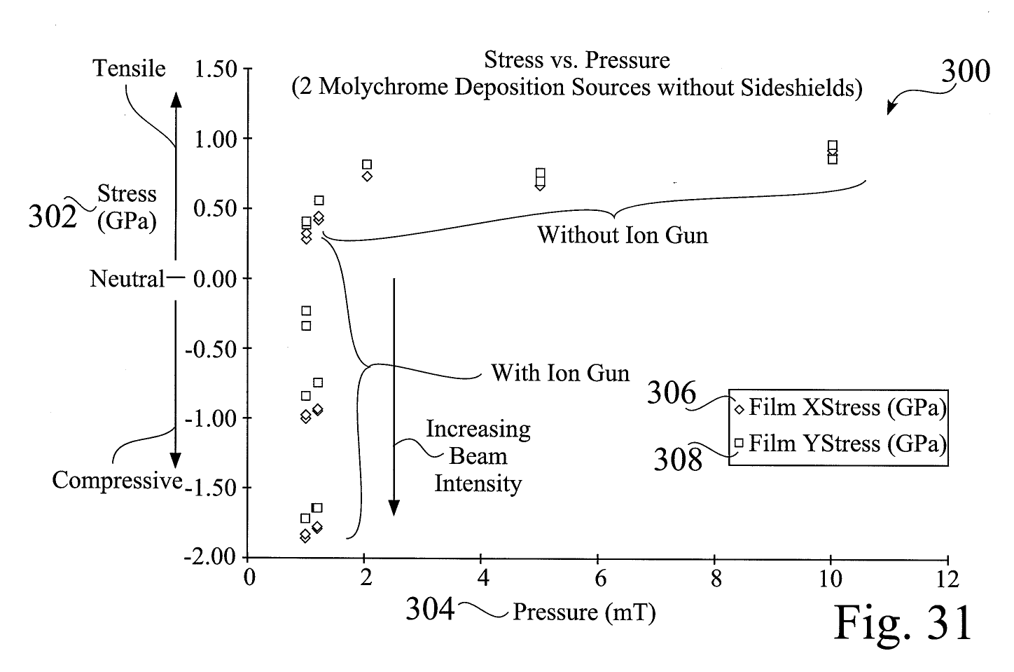

FIG. 31 is a chart 300 of experimentally obtained stress 302 vs. pressure 304 curve data 306,308 with MoCr deposited from targets without side shields 46. Data at 1 milli Torr was obtained with ion gun bombardment. As seen in FIG. 31, data associated without use of ion gun bombardment yielded a relatively low range of tensile stress, e.g. about 0.4 to 1.1 GPa, across a wide pressure range. As also seen in the exemplary data in FIG. 31, a relatively wider range of stress was attained when using an ion gun at different intensity levels.

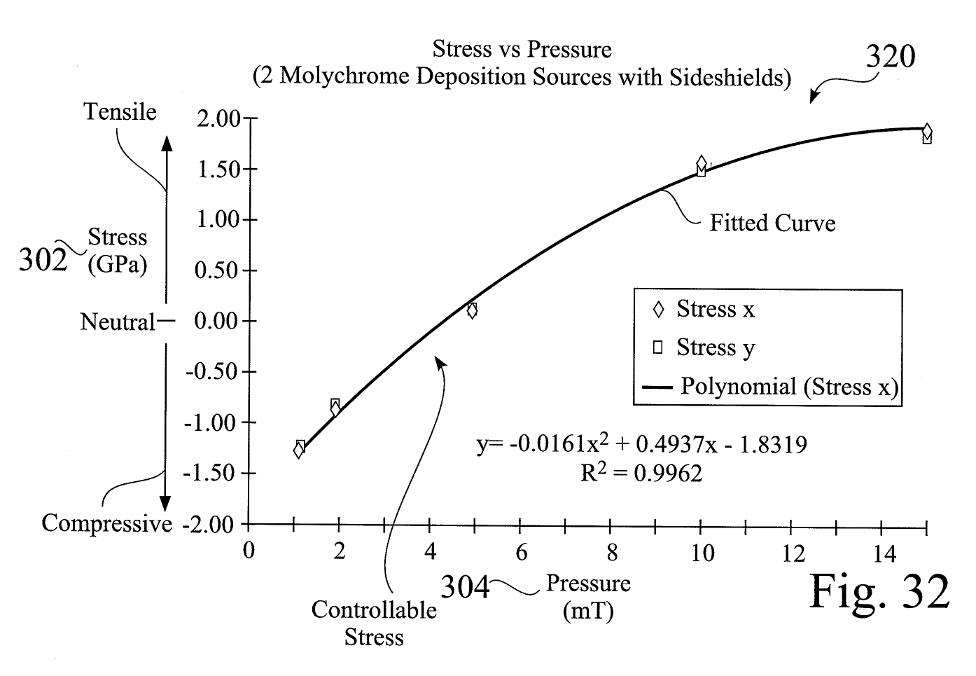

FIG. 32 is a chart 320 of experimentally obtained stress 302 vs. pressure 304 data and a related polynomial curve with MoCr deposited for a pair of linear magnetron sputtering sources 16 with side shields 46 and no ion gun bombardment. The side shields 46 were oriented at about 90 degrees with respect to one another in the apparatus 10b seen in FIG. 3 and FIG. 4, without the use of an ion gun 20. The data in FIG. 32 show a series of layers 174 fabricated at working gas pressures ranging from about 1.0 milli Torr to about 15 milli Torr with corresponding internal stresses ranging from about −1.25 GPa (compressive) to about 1.75 GPa (tensile).

It is typically preferred to deposit material 74 at as high a rate as possible, both to increase production throughput and to minimize the deleterious effect of co-depositing impurities from the background gasses in the vacuum chamber. Whereas the best quality films are formed at relatively high rates of rotation, both wear on the mechanical bearings and particulate generation can be minimized by reducing the rotation rate. In a production deposition system, the rotation rate may preferably be chosen so as to optimize the number of monolayers deposited per pass, i.e. to reduce the rotation rate by an amount that increases the number of monolayers deposited, without significantly degrading the desired film properties such as the uniformity of stress in the X, Y, and Z directions.

For example, at a typically time-averaged deposition rate of 0.5 nm/sec (1.8 um/hr or about 1.5 monolayers/sec), the plate 12 may rotate at 1 to 240 rpm. This rotation rate may be as much as about 10 times faster than is needed or desired in conventional planetary deposition, and about 100 times faster than the pass time in linear transport.

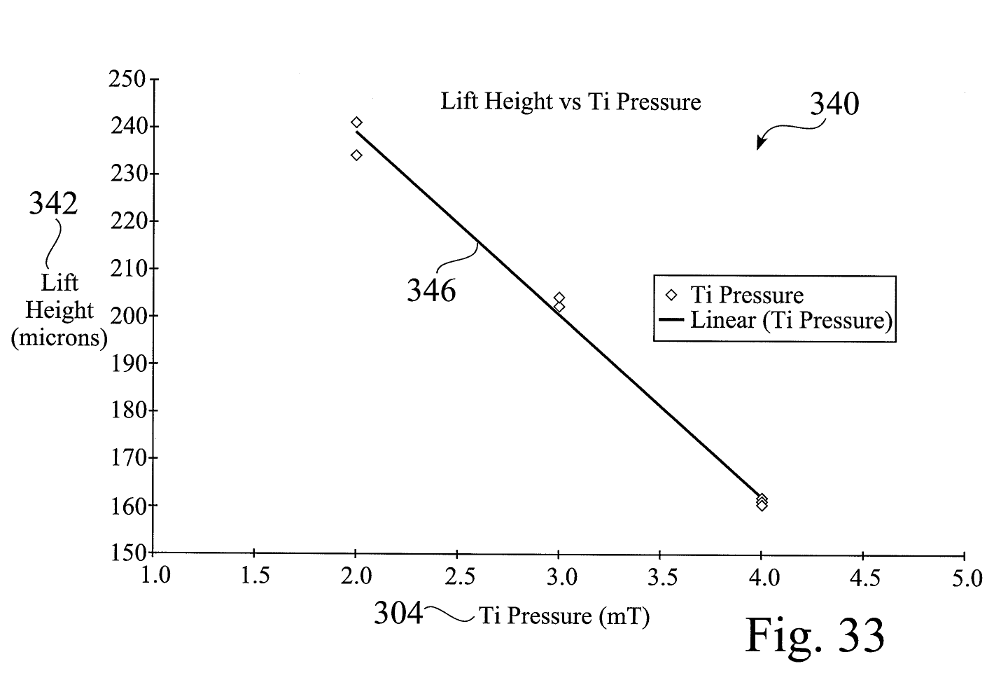

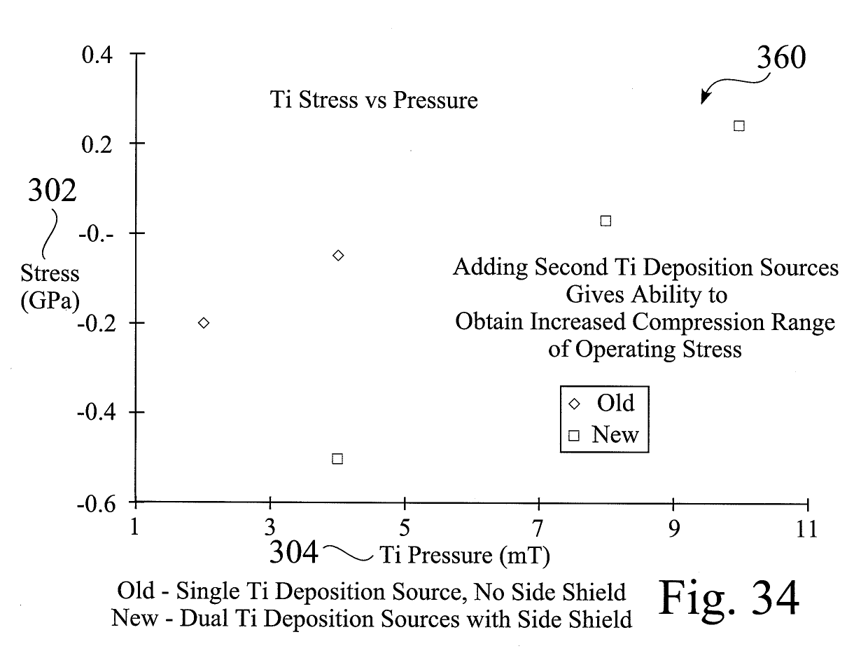

FIG. 33 is a chart 340 showing experimentally obtained spring lift height 342 vs. titanium deposition 304, and a calculated pressure curve 346. FIG. 34 is a chart 360 showing experimentally obtained titanium stress 302 vs. titanium deposition 304 pressure curve.

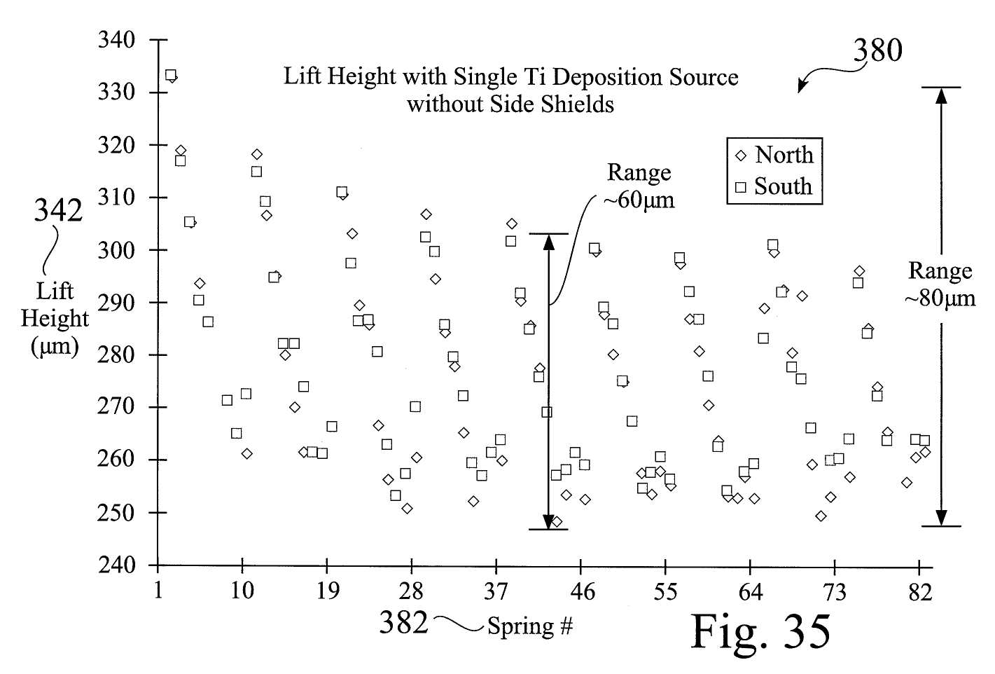

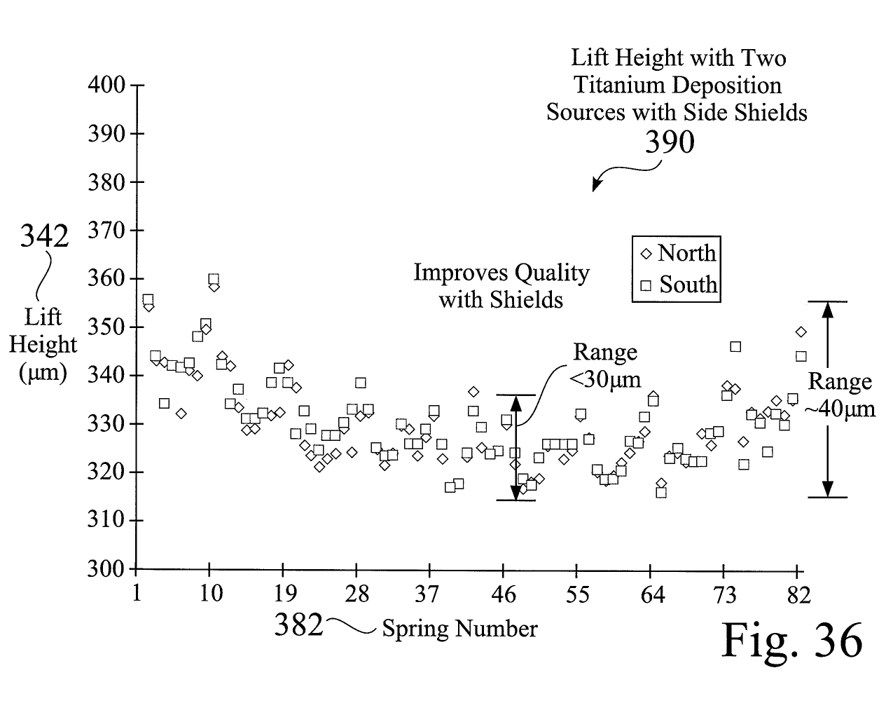

FIG. 35 is a chart 380 showing experimental data showing lift height 342 distribution as a function of spring number 382 across a 6″ substrate using a single titanium target 16 equipped with side shields 46. FIG. 36 is a chart 390 showing experimental data showing lift height 342 distribution as a function of spring number 382 across a 6″ substrate using dual titanium targets 16 equipped with side shields 46.

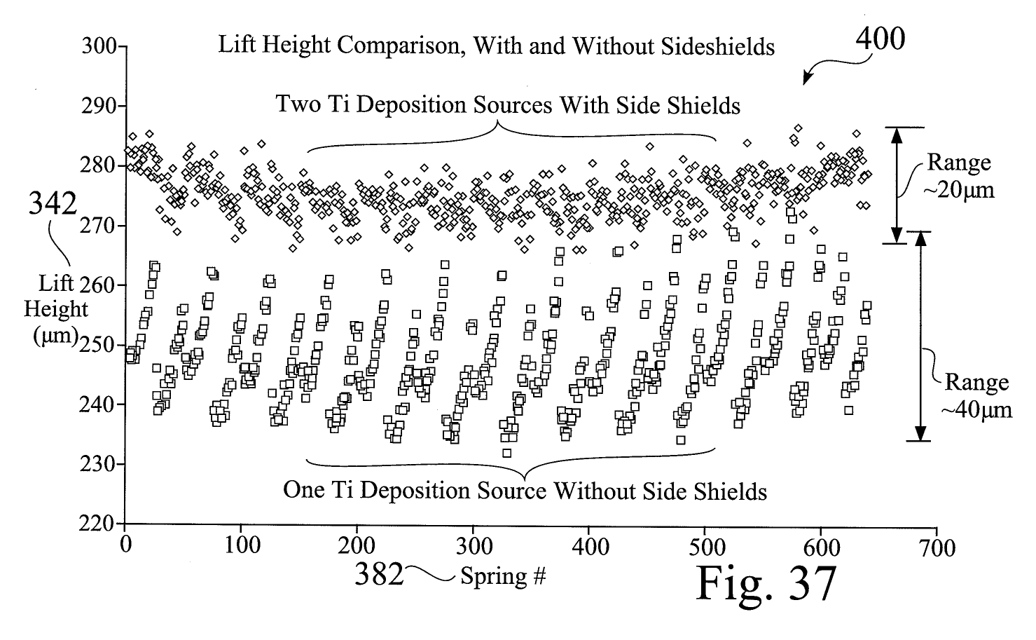

FIG. 37 is a chart 400 showing experimental data comparing lift height 342 distributions as a function of spring number 382 across a 4″ substrate using single and dual titanium targets 16 equipped with side shields 46.

In some embodiments of the enhanced sputtered film processing system 10 and method 150, measurement and/or compensation are provided for any of the lift height 262 and the X-Y position of photolithographically patterned spring contacts 246. For example, any of the spring length and angle may preferably be measured and/or adjusted on the photolithographic mask to compensate for any errors measured in produced spring substrate assemblies.

While some embodiments of the enhanced sputtered film processing system 10 and method 150 are implemented for the fabrication of photolithographically patterned springs 246 with lift heights and tip positions having predictable positional errors, the system 10 and method 150 may alternately be used for a wide variety of sputter deposition environments, such as to provide mechanical compliance and/or electrical connections between any of contacts, connectors, and/or devices or assemblies.

Accordingly, although the invention has been described in detail with reference to a particular preferred embodiment, persons possessing ordinary skill in the art to which this invention pertains will appreciate that various modifications and enhancements may be made without departing from the spirit and scope of the claims that follow.

1. An apparatus for depositing one or more layers on one or more substrates, said substrates having a front surface and an opposing back surface, comprising:
one or more sputter deposition sources, each sputter deposition source having a sputtering target comprising a spring material and a sputtering target surface from which the spring material is sputtered and one or more side shields extending therefrom for blocking at least a portion of relatively uncollimated sputtered spring material from reaching the one or more substrates to enable formation of one or more film layers with any of increased mechanical integrity and controllable levels of internal stress;
means for controllably moving any of the substrates and the sputter deposition sources with respect to each other, such that at least a portion of the relatively collimated sputtered spring material travels beyond the end of the respective side shields and is controllably deposited on the front surface of the substrates; and
means for controlling the sputter deposition conditions such that the one or more layers is formed with a controllable internal stress in a plane parallel to the one or more substrates up to the maximum internal stress that the spring material can sustain.

2. The apparatus of claim 1, wherein the spring material comprises any of MoCr, tungsten, tantalum and/or any combination thereof.

3. The apparatus of claim 1, wherein the means for controlling the sputter deposition conditions comprises any of pressure of a deposition gas, deposition source voltage, power, side shield geometry, and side shield-to-substrate spacing.

4. The apparatus of claim 3, wherein the deposition gas comprises an inert gas and argon.

5. The apparatus of claim 3, wherein the properties of the deposited layer comprise any of durability, resistance to set, lack of failure inducing defects, uniform crystallographic properties, uniform atomic structure, and uniform grain properties.

6. The apparatus of claim 1, wherein the sputter deposition sources are rectangular.

7. The apparatus of claim 1, wherein at least one of the side shields extends from a periphery of the respective sputter deposition source.

8. The apparatus of claim 1, wherein the substrates comprise an adhesion layer located on the front surface thereof.

9. The apparatus of claim 1, wherein the one or more deposition sources comprise two deposition sources, and wherein the two deposition sources are oriented at an angle with respect to each other.

10. The apparatus of claim 9, wherein the angle ranges from about 45 degrees to about 135 degrees.

11. The process of claim 9, wherein the angle is any of about 45 degrees, about 90 degrees, and about 120 degrees.

12. The apparatus of claim 1, wherein the side shields extend a distance from the sputtering target surface that is greater than the spacing between the side shield and the substrate.

13. The apparatus of claim 1, wherein the side shields contain internal subdivisions having shapes selected from the group comprising any of rectangles, squares, circles, and polygons.

14. The apparatus of claim 1, wherein the side shields are comprised of any of an electrically conductive material and an electrically insulating material.

15. The apparatus of claim 1, wherein the side shields are connected to a source of electrical potential comprising any of positive, negative, neutral, and AC potential.

16. The apparatus of claim 1, wherein at least two layers are formed on the substrates with different levels of internal stress.

17. The apparatus of claim 1, wherein the levels of internal stress comprise any of compressive, neutral, and tensile.

18. The apparatus of claim 1, wherein at least two layers are formed on the substrates and define a stress gradient in the plane parallel to the substrates ranging from any of compressive to neutral, neutral to tensile, compressive to tensile, neutral to compressive, tensile to neutral, and tensile to compressive.

19. The apparatus of claim 1, wherein the controllable internal stress is any of uniform and isotropic.

20. The apparatus of claim 1, further comprising:
at least one ion gun for any of sputter etching and surface cleaning of the substrates.

21. The apparatus of claim 1 further comprising:
at least one sputter deposition source for depositing any of an adhesion layer and a release layer on the substrates.

22. The apparatus of claim 1, wherein the spring metal layer comprises an elastic material.

23. The apparatus of claim 22, wherein the spring metal layer comprises a material chosen to maintain formed internal stress over fabrication process temperatures and subsequent operating temperatures.

24. The apparatus of claim 23, wherein the fabrication process temperatures are greater than or equal to 300 degrees C., and wherein the subsequent operating temperatures are greater than or equal to 200 degrees C.

25. The apparatus of claim 1, wherein the one or more deposition sources comprise two spring metal deposition sources, the apparatus further comprising:
a drive mechanism to impart planetary motion to the substrates such that the orientation of the substrates relative to each of the deposition sources remains constant as each of the substrates travels about its orbit and is located centrally when passing the deposition sources;
wherein successive layers of thin films are deposited onto the substrates as they repeatedly traverse each of the deposition sources; and
wherein the resulting film, comprising a plurality of thin film layers, is formed with substantially uniform thickness and isotropic properties.

26. The apparatus of claim 1, further comprising:
one or more ion guns for any of sputter etching and surface cleaning of any of the substrate and at least one of the deposited material layers.

27. The apparatus of claim 1, wherein the substrates are any of square and round.

28. The apparatus of claim 27, wherein the substrates are less than or equal to 100 mm on a side.

29. The apparatus of claim 27, wherein the substrates are greater than 100 mm on a side.

30. An apparatus for depositing a film on substrates by sputter deposition, comprising:
a substrate holder for receiving at least one substrate and being affixed to a substantially circular carrier plate, wherein both the substrate and the carrier plate synchronously rotate about their respective normal axes;
at least two elongated substantially identical deposition sources that are angularly spaced to average out X-Y anisotropy in a plane parallel to the substrate, said sources comprising substantially the same materials and operated to provide substantially the same deposition characteristics having a long dimension positioned parallel to a carrier plate radius, with their surfaces facing the substrate substantially coplanar, said long dimension being substantially larger than a substrate dimension, and having a small perpendicular distance between substrate and deposition source surfaces;
at least one side shield extending from the surface of the respective deposition sources toward the substrate for any of increasing mechanical integrity and controlling levels of internal stress of one or more formed film layers on the substrate;
means for initiating a sputter deposition process by striking a plasma at sub-atmospheric gas pressure inside a deposition chamber as the carrier plate rotates about its normal axis along with the affixed substrate, which additionally undergoes a concomitant rotation about its own normal axis, as measured relative to the carrier plate, with equal and opposite angular velocity as that of the rotating carrier plate, wherein the orientation of the at least one substrate relative to each of the deposition sources remains constant as the carrier plate rotates;
wherein successive layers of thin films are deposited onto the substrate as it repeatedly traverses each of the deposition sources; and
wherein the resulting film, comprising a plurality of thin film layers, is formed with substantially uniform thickness and isotropic properties.

31. A method for depositing a film on substrates by sputter deposition, comprising the steps of:
providing a substrate holder for receiving at least one substrate, said substrate holder being affixed to a substantially circular carrier plate, wherein both the substrate and the carrier plate can synchronously rotate about their respective normal axes;
providing at least two elongated, substantially identical deposition sources that are angularly spaced to average out X-Y anisotropy in a plane parallel to the substrate, said sources comprising substantially the same materials and operated to provide substantially the same deposition characteristics, having a long dimension positioned parallel to a carrier plate radius, with their surfaces facing the substrate substantially coplanar, said long dimension being substantially larger than a substrate dimension, and having a small perpendicular distance between substrate and deposition source surfaces;
providing at least one side shield extending from the surfaces of the respective deposition sources toward the substrate for any of increasing mechanical integrity and controlling levels of internal stress of one or more formed film layers on the substrate;
initiating a sputter deposition process by striking a plasma at sub-atmospheric gas pressure inside a deposition chamber as the carrier plate rotates about its normal axis along with the affixed substrate, which additionally undergoes a concomitant rotation about its own normal axis, as measured relative to the carrier plate, with equal and opposite angular velocity as that of the rotating carrier plate wherein orientation of the substrate relative to each deposition source remains constant as the carrier plate rotates; and
depositing successive layers of thin films onto the substrate as it repeatedly traverses each of the deposition sources;
wherein the resulting film, comprising a plurality of thin film layers, is formed with substantially uniform thickness and isotropic properties.

32. A process, comprising the steps of:
providing one or more substrates having a front surface and an opposing back surface;
providing one or more sputter deposition sources, each deposition source having a sputtering target comprising a spring material and a sputtering target surface from which the spring material is sputtered;
providing one or more side shields extending from the sputtering target surface for blocking at least a portion of relatively uncollimated sputtered spring material from reaching the one or more substrates to enable formation of one or more film layers with any of increased mechanical integrity and controllable levels of internal stress;
controllably moving the substrates and the deposition targets with respect to each other, such that at least a portion of the relatively collimated sputtered spring material travels beyond the side shields and is deposited on the front surface of the substrates; and
controlling the sputter deposition conditions such that the one or more layer is formed with a controllable internal stress in a plane parallel to the substrates up to the maximum internal stress that the spring material can sustain.

33. The process of claim 32, wherein the spring material comprises any of MoCr, tungsten, tantalum and/or any combination thereof.

34. The process of claim 32, wherein the sputter deposition conditions comprise any of pressure, deposition source voltage, power, side shield geometry, and side shield to substrate spacing.

35. The process of claim 32, wherein the internal stress is any of compressive, neutral, and tensile.

36. The process of claim 32, wherein at least one of the side shields extends from a periphery of at least one of the deposition targets.

37. The process of claim 32, wherein the provided substrates have an adhesion layer located on the front surface.

38. The process of claim 32, further comprising the steps of:
repositioning the relative planar position of any of the substrates and the targets with respect to each other; and
returning to the film deposition step.

39. The process of claim 32, wherein the one or more deposition sources comprise two deposition sources, and wherein the two deposition sources are oriented at an angle with respect to each other.

40. The process of claim 39, wherein the angle ranges from about 45 degrees to about 135 degrees.

41. The process of claim 39, wherein the angle is any of about 45 degrees, about 90 degrees, and about 120 degrees.

42. The process of claim 32, wherein the side shields extend a distance from the sputtering target surface that is greater than the spacing between the side shield and the substrates.

43. The process of claim 32, wherein the side shields contain internal subdivisions having shapes selected from the group comprising any of rectangles, squares, circles and polygons.

44. The process of claim 32, wherein the side shields are comprised of any of an electrically conductive material and an electrically insulating material.

45. The process of claim 32, wherein the side shields are connected to a source of electrical potential comprising any of positive, negative, neutral, and AC potential.

46. The process of claim 32, wherein at least two layers are formed with different levels of internal stress.

47. The process of claim 46, wherein the internal stress is any of uniform and isotropic.

48. The process of claim 46, wherein the internal stress is uniform and isotropic.

49. The process of claim 46, wherein the internal stress is any of compressive, neutral, and tensile.

50. The process of claim 32, wherein the substrates comprise any of ceramic, silicon, glass, glass ceramic, diamond, FR4, printed circuit board, a polymer, polyimide, and combinations thereof.

51. A process, comprising the steps of:
providing a substrate having a front surface and an opposing back surface;
forming an adhesion layer on the front surface of the substrate, the adhesion layer comprising at least two sputter deposited film layers laminated to comprise a substantially uniform thickness and an inherent level of isotropic stress;
forming a composite spring layer on the adhesion layer, the composite spring layer comprising at least two sputter deposited film layers laminated to comprise a substantially uniform thickness and isotropic properties;
forming at least one spring by photolithographically removing at least a portion of the composite spring layer and the adhesion layer; and
chemically removing the adhesion layer between at least a portion of the photolithographically formed springs;
wherein the resulting springs comprise a fixed portion attached to the substrate and a free portion extending away from the substrate to a spring tip, the tip having a controllable lift height and tip position.

52. The process of claim 51, wherein the adhesion layer comprises any of compressive, neutral and tensile stress.

53. The process of claim 51, wherein at least two of the sputter deposited film layers of the composite spring layer are formed on the substrate with different levels of internal stress.

54. The process of claim 51, wherein at least two of the sputter deposited film layers of the composite spring layer define a stress gradient in the plane parallel to the substrate ranging from any of compressive to neutral, neutral to tensile, compressive to tensile, neutral to compressive, tensile to neutral, and tensile to compressive.

55. The process of claim 51, wherein the substrate is any of square and round.

56. The process of claim 55, wherein the substrate is less than or equal to 100 mm on a side.

57. The process of claim 55, wherein the substrate is greater than 100 mm on a side.

58. The process of claim 51, wherein the substrate comprises any of ceramic, silicon, glass, glass ceramic, diamond, FR4, printed circuit board, a polymer, polyimide, and any combination thereof.

59. The process of claim 51, wherein the sputter deposited film layers associated with any of the adhesion layer and the composite spring layer are formed by one or more sputter deposition sources.

60. The process of claim 59, wherein the sputter deposition sources are rectangular.

61. The process of claim 51, wherein at least one of the sputter deposition sources comprises a side shield extending therefrom toward the substrate.

62. The process of claim 51, wherein the adhesion layer comprises a chemically dissolvable material.

63. The process of claim 51, wherein the adhesion layer comprises any of titanium, chromium, nitride and any combination thereof.

64. The process of claim 51, wherein the composite spring layer comprises a material chosen to maintain formed internal stress over fabrication process temperatures and subsequent operating temperatures.

65. The process of claim 64, wherein the fabrication process temperatures are greater than or equal to 300 degrees C., and wherein the subsequent operating temperatures are greater than or equal to 200 degrees C.

66. The process of claim 51, wherein the composite spring layer comprises any of MoCr, tungsten, tantalum and/or any combination thereof.

67. A method, comprising the steps of:
fabricating a first device on a first substrate comprising at least one spring contact with measurable properties;
measuring the errors in the measurable properties of the at least one spring contact associated with the first device;
determining an error correction matrix associated with the measured errors; and
modifying the fabrication process based on the determined error matrix, to reduce errors in the properties of subsequent spring contacts fabricated on subsequent devices.

68. The method of claim 67, wherein the measurable properties comprise any of spring contact length, width, shape, angular orientation, tip height and tip position.

69. A process, comprising the steps of:
fabricating a first calibration spring array of photolithographically patterned springs on a substrate, each member of the calibration spring array being positionally distributed over a designated area of the substrate, at least one photomask used in fabricating the calibration spring array such as to define any of the length, width, shape, angular orientation, and position of each spring in the calibration spring array;
measuring the errors in any of the length, width, shape, angular orientation, position, spring lift height, and tip position of each member of the fabricated calibration spring array;
determining an error correction matrix for each member or the calibration spring array; and
compensating a second device spring array for any errors in any of the length, width, shape, angular orientation, position, spring lift height, and tip position in the vicinity of each member of the fabricated calibration spring array using the correction matrix to adjust the photolithographic pattern on at least one photomask used to fabricate the device spring array such as by changing any of the length, width, shape, angular orientation, and position of the each member of the device spring array relative to the substrate to reduce any errors in spring lift height and tip position of any of the one or more photolithographically patterned springs in the device.
